(19) United States
(12) Patent Application Publication
(10) Pub. No.: US 2016/0295710 A1
(43) Pub. Date: Oct. 6, 2016

(54) ELECTRONIC APPARATUS, MOTOR VEHICLE EQUIPPED WITH ELECTRONIC APPARATUS, DISPLAY DEVICE, AND MOBILE DEVICE EQUIPPED WITH DISPLAY DEVICE

(71) Applicant: PANASONIC INTELLECTUAL PROPERTY MANAGEMENT CO., LTD., Osaka (JP)

(72) Inventors: TOMOKI UEYAMA, Kanagawa (JP); KENJI TAKAYAMA, Kanagawa (JP); KATSUHIKO SAKUMA, Kanagawa (JP); YUJI ISEKI, Kanagawa (JP)

(21) Appl. No.: 14/891,348

(22) PCT Filed: Jul. 10, 2014
(86) PCT No.: PCT/JP2014/003665

§ 371 Date: Nov. 14, 2015

(30) Foreign Application Priority Data
Jul. 11, 2013 (JP) 2013-145215

(51) Int. Cl. H05K 5/00; B60R 11/02; H05K 5/02; H05K 7/14

(52) U.S. Cl. CPC H05K 5/0017; H05K 5/0069; H05K 7/1417; B60R 11/0229; H05K 7/1427; H05K 5/02

(57) ABSTRACT

For achieving this object, the present invention includes a body case (4), and an electric circuit board (18) disposed inside the body case (4). The body case (4) includes a carbon fiber sheet (12), a resin layer (13) covering the sheet (12), and a conductive nut (14) fixed to the sheet (12) with caulking. The electric circuit board (18) includes an earth pattern (19), and a through hole (20) provided in the earth pattern (19) or in a vicinity of the earth pattern (19). A conductive bolt (22) is fastened through the through hole (20) of the electric circuit board (18) into the nut (14) from a side opposite to the nut (14) to electrically connect the earth pattern (19) of the electric circuit board (18) with the sheet (12) of the body case (4) via the nut (14).

### TECHNICAL FIELD

The present invention relates to an electronic apparatus, a motor vehicle equipped with an electronic apparatus, a display device, and a mobile device, such as a motor vehicle and an airplane, equipped with a display device.

### BACKGROUND ART

There has been a proposed electronic apparatus that includes a body case which is made of resin containing carbon fibers (see PTL 1, PTL 2, and PTL 3).

In case of an electronic apparatus described in PTL 1, an earth pattern of an electric circuit board is connected with carbon fibers having conductivity, for example, to make earth connection.

According to a specific configuration of an electronic apparatus described in PTL 1, a body case and a tapping screw are formed integrally with each other from resin containing carbon fibers. An electric circuit board is placed on the tapping screw. A conductive bolt is fastened from a side opposite to the tapping screw through a through hole of the electric circuit board toward the tapping screw to make electric connection between an earth pattern of the electric circuit board and the body case via the tapping screw.

According to a configuration of an electronic apparatus described in PTL 1, a body case and a projection for tapping screw are formed integrally with each other from resin containing carbon fibers. An electric circuit board or electric circuit part is placed on the projection. A tapping screw is fastened from a side opposite to the projection through a through hole of the electric circuit board or electric circuit part toward the projection to fix the electric circuit board or electric circuit part to an inner surface of the body case.

PTL 2 proposes an electronic apparatus which increases strength of a body case by adding carbon fibers to the body case.

More specifically, the body case is made of resin containing carbon fibers to increase the strength of the body case. In this case, a part of a surface of the body case includes an area through which carbon fibers are not exposed so as to secure insulation from electronic parts.

PTL 3 discloses an electronic apparatus which includes a cover made of carbon fiber reinforced plastics (Carbon Fiber Reinforced Plastics).

For example, there is a type of mobile devices, such as a motor vehicle and an airplane, which is equipped with a display device embedded on an upper rear side of a front seat and used by a passenger sitting on a rear seat. However, when the display device is embedded on the upper rear side of the front seat for use by the passenger sitting on the rear seat, a wide directional change of the display device becomes difficult.

One of ideas for overcoming this problem is to use an attachment shaft that attaches the display device to the rear side of the front seat in an exposed state.

However, the display device attached in an exposed state may be subjected to naughty treatment by a child, such as an action of hanging from the display device exposed. Accordingly, a cover of the display device for covering an outer periphery or a rear side of a display unit needs to be constituted by a rigid metal case to increase strength of the display device.

However, when the cover is constituted by a rigid metal case, weight of the cover increases. This increase in weight is not preferable for the mobile device such as a motor vehicle and an airplane in view of safety at the time of a sudden stop.

One of ideas for overcoming this problem is to use a cover made of carbon fiber reinforced plastics (Carbon Fiber Reinforced Plastics).

### CITATION LIST

### Patent Literature

PTL 1: Unexamined Japanese Patent Publication No. 2002-118371

PTL 2: Unexamined Japanese Patent Publication No. 2006-278568

PTL 3: Unexamined Japanese Patent Publication No. 2005-149463

### SUMMARY OF THE INVENTION

### Technical Problems

According to the electronic apparatus described in PTL 1, the body case and the tapping screw are formed integrally with each other from resin containing carbon fibers. In this case, a sufficient amount of carbon fibers are difficult to be added to resin forming a portion of the tapping screw. Accordingly, earth connection becomes insufficient.

More specifically, an amount of carbon fibers added to resin needs to be reduced to secure fluidity of the resin. In this case, earth connection between the tapping screw containing a reduced amount of carbon fibers and the earth pattern of the electric circuit board becomes insufficient.

According to the electronic apparatus disclosed in PTL 1, the body case and the projection for tapping screw are formed integrally with each other from resin containing carbon fibers. In this case, carbon fibers are also added to a portion of the projection. Accordingly, the tapping screw screwed into the projection may be damaged by carbon fibers, in which case fixation of the electric circuit board or electric circuit part may become insufficient.

More specifically, carbon fibers having considerably high hardness damage the tapping screw when the tapping screw rubs against carbon fibers. In this case, fixation of the electric circuit board or electric circuit part becomes insufficient.

According to the electronic apparatus described in PTL 2, the body case is made of resin containing carbon fibers. Accordingly, strength of the body case increases.

In addition, the area through which carbon fibers are not exposed is formed in a part of the surface of the body case. Accordingly, insulation between the body case and the electronic parts is secured in this area.

However, the area containing no carbon fiber is formed only on the surface of the body case, wherefore carbon fibers are still present in an inner part of this area. In this state, an antenna unit provided inside the body case is difficult to communicate with an external device.

More specifically, a large number of electronic apparatuses containing Wi-Fi or other communication units have been put on the market in recent years, for example. When the body case included in these types of electronic apparatus is made of resin containing carbon fibers as in the foregoing case, communication between the antenna unit and the external device becomes difficult due to conductivity of the carbon fibers.

The cover made of carbon fiber reinforced plastics as described in PTL 3 has high strength and is lightweight. Accordingly, problems in safety are not caused even when the display device is a type exposed from the front seat.

However, the carbon fiber reinforced plastics, which are hard and fragile, may scratch the attachment shaft, or are partially broken at a contact portion between the cover and the attachment shaft.

Moreover, when a broken piece of the carbon fiber reinforced plastics enters the inside of the cover, an electronic circuit may be short-circuited due to conductivity of the carbon fiber reinforced plastics.

### Solution to Problems

An electronic apparatus according to the present invention includes: a body case; and an electric circuit board disposed inside the body case. The body case includes a carbon fiber sheet, a resin layer covering the sheet, and a conductive nut fixed to the sheet with caulking. The electric circuit board includes an earth pattern, and a first through hole provided in the earth pattern or in a vicinity of the earth pattern. A conductive bolt is fastened through the first through hole of the electric circuit board into the nut from a side opposite to the nut. The earth pattern of the electric circuit board is electrically connected with the body case via the nut.

An electronic apparatus according to the present invention includes: a body case; and an electric circuit board or electric circuit part attached to an inner surface side of the body case. The body case includes a carbon fiber sheet, a resin layer covering each of front and rear surfaces of the sheet, and a projection formed inside the body case by raising a part of the resin layer in a portion of a first through hole formed in the sheet. The electric circuit board or electric circuit part includes a second through hole. A tapping screw is fastened from a side opposite to the projection through the second through hole toward the projection.

An electronic apparatus according to the present invention includes: a body case; and an electric circuit board disposed inside the body case. The body case includes a carbon fiber sheet, and a resin layer covering the sheet. The electric circuit board includes a communication unit, and an antenna unit connected with the communication unit. An opening is formed in the sheet at a portion facing the antenna unit. The resin layer is provided inside the opening.

A display device according to the present invention includes: a display unit; a cover that covers an outer peripheral side or a rear side of the display unit; and a cylindrical or bar-shaped attachment shaft that attaches the cover to a seat constituent. The cover is made of carbon fiber reinforced plastics (Carbon Fiber Reinforced Plastics). The cover includes an insertion hole through which a part of the attachment shaft is inserted into the cover. A cylindrical bearing is attached to the insertion hole. A part of the attachment shaft is inserted through a through hole of the bearing into the cover.

### Advantageous Effects of Invention

According to the present invention, an earth pattern of an electric circuit board is electrically connected with a carbon fiber sheet via a nut. Accordingly, earth connection to the earth pattern of the electric circuit board strengthens.

According to the present invention, carbon fibers are not contained in a projection, and thus do not damage a tapping screw. Accordingly, insufficient fixation of the electric circuit board or electric circuit part to an inner surface of a body case is avoidable.

According to the present invention, the carbon fibers are not contained in an area of an opening of the sheet constituting the body case. Accordingly, an antenna unit provided inside the body case and facing this area is allowed to communicate with a device outside the body case.

According to the present invention, a rubbing state between an attachment shaft and an insertion hole of a cover made of carbon fiber reinforced plastics is not produced at the time of so-called tilt adjustment for adjusting a tilt of a display unit. Accordingly, damage to the cover or the attachment shaft is avoidable.

### BRIEF DESCRIPTION OF DRAWINGS

FIG. 1 is a perspective view illustrating an electronic apparatus provided inside a motor vehicle according to a first exemplary embodiment of the present invention.

FIG. 2 is a front view of the electronic apparatus.

FIG. 3 is a rear view of the electronic apparatus.

FIG. 4 is a control block diagram of the electronic apparatus.

FIG. 5 is a perspective view of a part of a body case of the electronic apparatus as viewed from an inside.

FIG. 6 is a perspective view of the part of the body case of the electronic apparatus as viewed from an outside.

FIG. 7 is an exploded perspective view of the part of the body case of the electronic apparatus as viewed from the inside.

FIG. 8 is a cross-sectional view illustrating a part of an inside of the body case of the electronic apparatus.

FIG. 9 is a perspective view illustrating a manufacturing method of the body case of the electronic apparatus.

FIG. 10 is a perspective view illustrating the manufacturing method of the body case of the electronic apparatus.

FIG. 11 is a cross-sectional view illustrating the manufacturing method of the body case of the electronic apparatus.

FIG. 12 is a perspective view illustrating the manufacturing method of the body case of the electronic apparatus.

FIG. 13 is a cross-sectional view illustrating the manufacturing method of the body case of the electronic apparatus.

FIGS. 14A and 14B are cross-sectional views illustrating the manufacturing method of the body case of the electronic apparatus.

FIGS. 15A and 15B are cross-sectional views illustrating the manufacturing method of the body case of the electronic apparatus.

FIGS. 16A and 16B are cross-sectional views illustrating the manufacturing method of the body case of the electronic apparatus.

FIG. 17 is a cross-sectional view illustrating the manufacturing method of the body case of the electronic apparatus.

FIG. 18 is a perspective view of a part of a body case of an electronic apparatus as viewed from an inside according to a second exemplary embodiment of the present invention.

FIG. 19 is a perspective view of a part of the body case of the electronic apparatus as viewed from an outside.

FIG. 20 is an exploded perspective view of the part of the body case of the electronic apparatus as viewed from the inside.

FIG. 21 is a cross-sectional view illustrating a part of an inside of the body case of the electronic apparatus.

FIG. 22 is a perspective view illustrating a manufacturing method of the body case of the electronic apparatus.

FIG. 23 is a perspective view illustrating the manufacturing method of the body case of the electronic apparatus.

FIG. 24 is a cross-sectional view illustrating the manufacturing method of the body case of the electronic apparatus.

FIG. 25 is a cross-sectional view illustrating a part of the body case of the electronic apparatus.

FIG. 26 is a cross-sectional view illustrating a part of a body case of an electronic apparatus according to a first modified example of the second exemplary embodiment.

FIG. 27 is a cross-sectional view of the electronic apparatus.

FIG. 28 is a cross-sectional view illustrating a part of a body case of an electronic apparatus according to a second modified example of the second exemplary embodiment.

FIG. 29 is a cross-sectional view of the electronic apparatus.

FIG. 30 is a control block diagram of an electronic apparatus according to a third exemplary embodiment.

FIG. 31 is a perspective view of a part of a body case of the electronic apparatus as viewed from an inside.

FIG. 32 is a perspective view of the part of the body case of the electronic apparatus as viewed from an outside.

FIG. 33 is an exploded perspective view of the part of the body case of the electronic apparatus as viewed from the inside.

FIG. 34 is a perspective view illustrating a manufacturing method of the body case of the electronic apparatus.

FIG. 35 is a perspective view illustrating the manufacturing method of the body case of the electronic apparatus.

FIG. 36 is a cross-sectional view illustrating the manufacturing method of the body case of the electronic apparatus.

FIG. 37 is a cross-sectional view illustrating a part of the body case of the electronic apparatus.

FIG. 38 is a cross-sectional view illustrating a part of an inside of the body case of the electronic apparatus.

FIG. 39 is a cross-sectional view of the body case of the electronic apparatus.

FIG. 40 is a cross-sectional view illustrating a part of a body case of an electronic apparatus according to another exemplary embodiment of the present invention.

FIG. 41 is a cross-sectional view illustrating a part of the body case of the electronic apparatus.

FIG. 42 is a perspective view illustrating a front seat which is provided inside a motor vehicle equipped with a display device according to a fourth exemplary embodiment of the present invention.

FIG. 43 is a perspective view of the front seat.

FIG. 44 is a perspective view illustrating the front seat including a cutout portion.

FIG. 45 is a perspective view illustrating the front seat including a cutout portion.

FIG. 46 is a side view of the display device.

FIG. 47 is a rear view of the display device.

FIG. 48 is a front view of the display device.

FIG. 49 is a top view of the display device.

FIG. 50 is a control block diagram of the display device.

FIG. 51 is a perspective view of a cover of the display device.

FIG. 52 is a side view of the cover of the display device.

FIG. 53 is an exploded perspective view of an attachment shaft portion of the display device.

FIG. 54 is a vertical cross-sectional view of the attachment shaft portion of the display device.

FIG. 55 is a vertical cross-sectional view of the attachment shaft portion of the display device.

FIG. 56 is a perspective view of an inside of the cover of the display device.

FIG. 57 is a vertical cross-sectional view of a portion between attachment shafts of the display device.

FIG. 58 is a partial cross-sectional view of a cover of a display device according to a fifth exemplary embodiment of the present invention.

FIG. 59 is a partial cross-sectional view of the cover.

FIG. 60 is an exploded perspective view of the display device.

FIG. 61 is a partial cross-sectional view of a cover of a display device according to a sixth exemplary embodiment of the present invention.

FIG. 62 is a partial cross-sectional view of the cover.

FIG. 63 is an exploded perspective view of a cover portion.

FIG. 64 is a vertical cross-sectional view of an attachment shaft portion of a display device according to a seventh exemplary embodiment of the present invention.

FIG. 65 is a vertical cross-sectional view of the attachment shaft portion of the display device.

### DESCRIPTION OF EMBODIMENTS

### First Exemplary Embodiment

A purpose of an invention described in a first exemplary embodiment is to strengthen earth connection of an earth pattern of an electric circuit board.

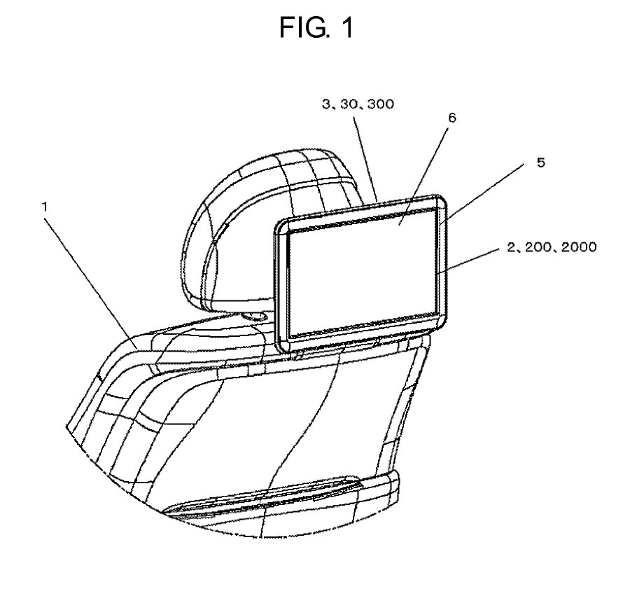

A reference number 1 in FIG. 1 indicates a driver's seat provided inside a motor vehicle, for example. Electronic apparatus 2 is provided on a rear side of driver's seat 1.

As illustrated in FIGS. 1 through 3, electronic apparatus 2 has a shape of a housing constituted by a combination of body case 3 on a front side and body case 4 on a rear side. Display unit 6 is exposed through opening 5 formed in body case 3.

Accordingly, in case of a configuration in this exemplary embodiment, a passenger sitting on a rear seat (not shown) enjoys images shown on display unit 6.

More specifically, controller 7, power source unit 8, memory 9, audio output unit 10, and reproduction unit 11 illustrated in FIG. 4 are provided inside body cases 3 and 4. Power source unit 8, memory 9, audio output unit 10, and reproduction unit 11 are connected with controller 7, as well as display unit 6 connected with controller 7.

As well known, reproduction unit 11 is a TV receiver, a radio receiver, or a music or image reproduction unit, for example.

Memory 9 stores operation programs or others.

Accordingly, with selection of an item to be reproduced of reproduction unit 11, an image is output to display unit 6, while a voice is output to a speaker (not shown) via audio output unit 10.

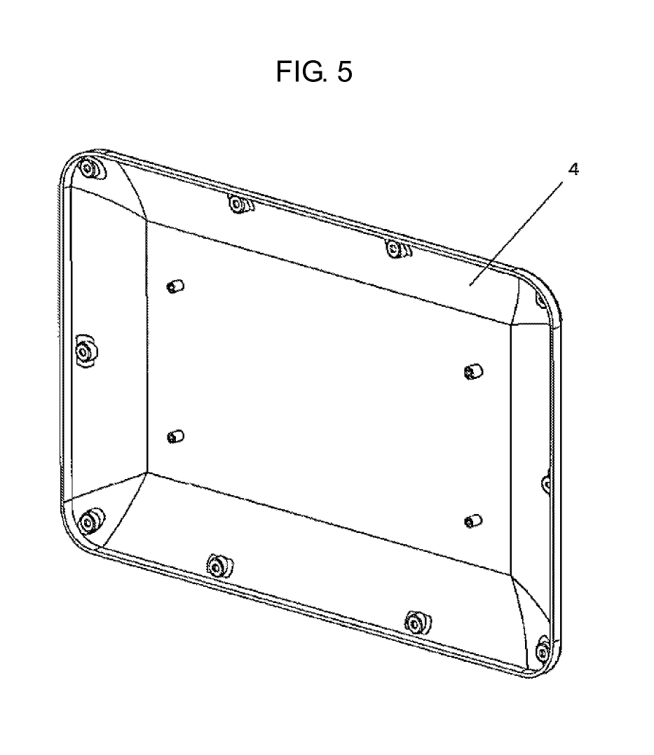

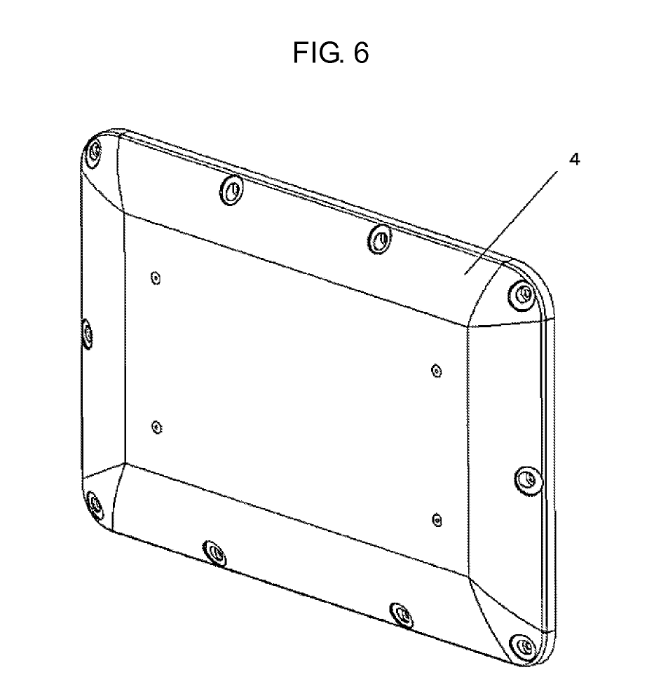

A feature of this exemplary embodiment lies in a structure of body case 4 illustrated in FIGS. 5 through 8.

More specifically, body case 4 includes carbon fiber sheet 12, resin layer 13 covering each of front and rear surfaces of sheet 12, and conductive nuts 14 fixed to sheet 12 with caulking.

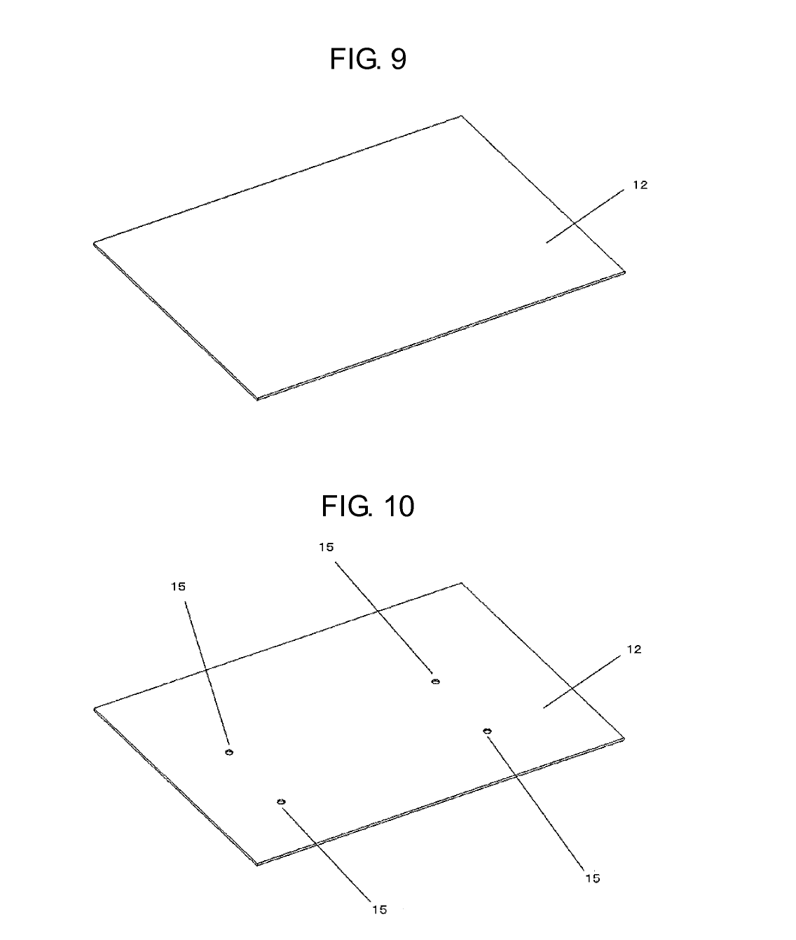

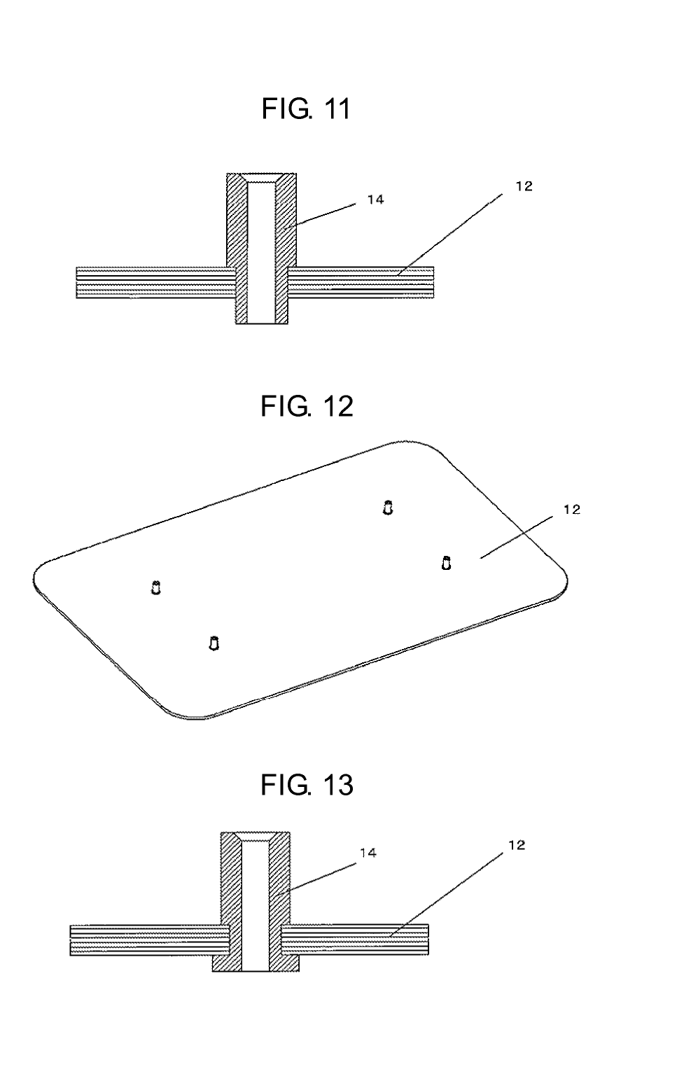

Detailed explanation further continues. At the time of manufacture of body case 4, rectangular carbon fiber sheet 12 is initially prepared as illustrated in FIG. 9. Subsequently, through holes 15 are formed at four positions of sheet 12 as illustrated in FIG. 10. Then, conductive nut 14 is attached to each of through holes 15 as illustrated in FIG. 11.

Each of conductive nuts 14 has a cylindrical shape. An outer circumference diameter of one end side (lower end side in FIG. 11) of nut 14 is made smaller. This one end side is inserted into through hole 15 in such a manner as to penetrate through hole 15.

In this state, the one end side of nut 14 (lower end side in FIG. 11) penetrating through hole 15 of sheet 12 is caulked in a direction of an outer circumference of through hole 15 of carbon fiber sheet 12 as illustrated in FIGS. 12 and 13 to fix nut 14 to a portion of through hole 15 of sheet 12 with caulking.

After completion of this caulking fixation, cutting work for rounding an outer periphery of sheet 12 is also performed.

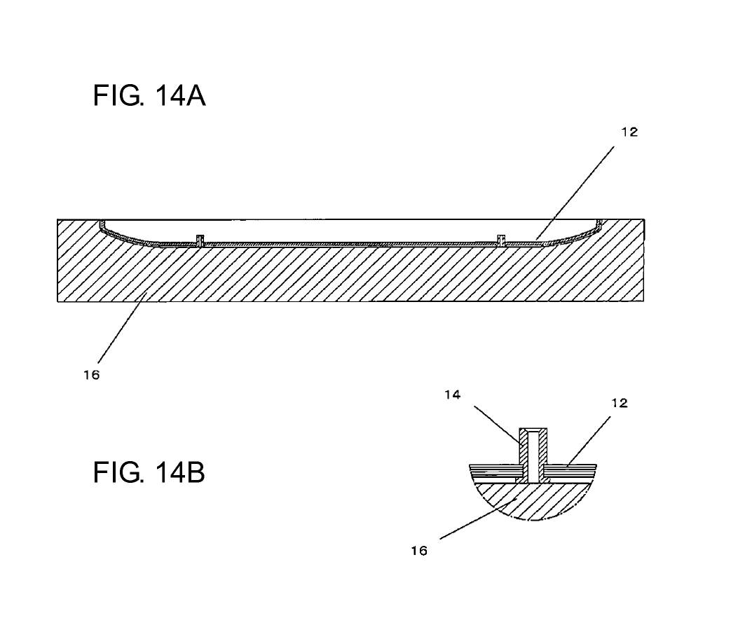

Then, sheet 12 is disposed inside lower mold 16 as illustrated in FIGS. 14A and 14B.

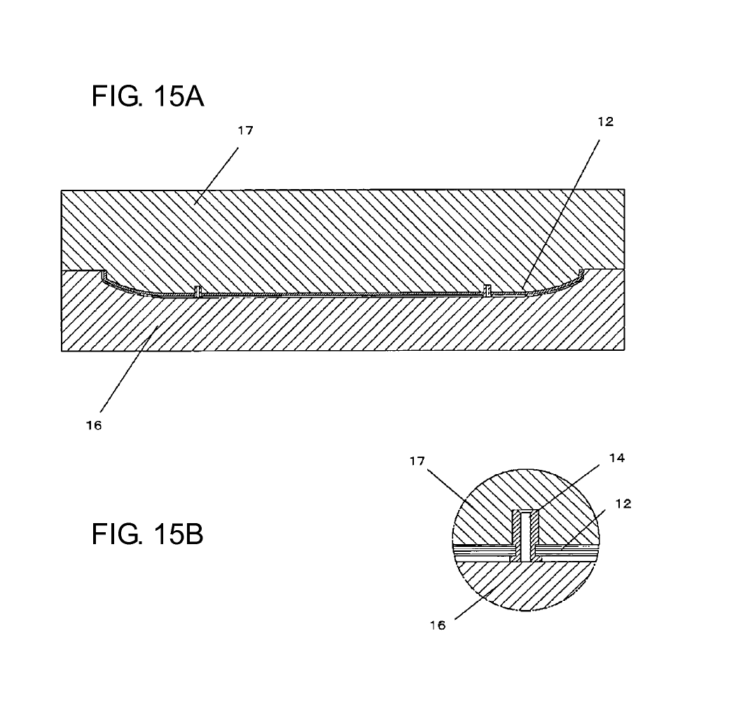

In this case, a caulked portion in the outer circumferential direction of through hole 15 of carbon fiber sheet 12 is present on the one end side of each nut 14 (lower end side in FIG. 11) as illustrated in FIGS. 14A and 14B and FIGS. 15A and 15B. Accordingly, sheet 12 is raised from a surface of lower mold 16 (space-produced state) at the corresponding portions.

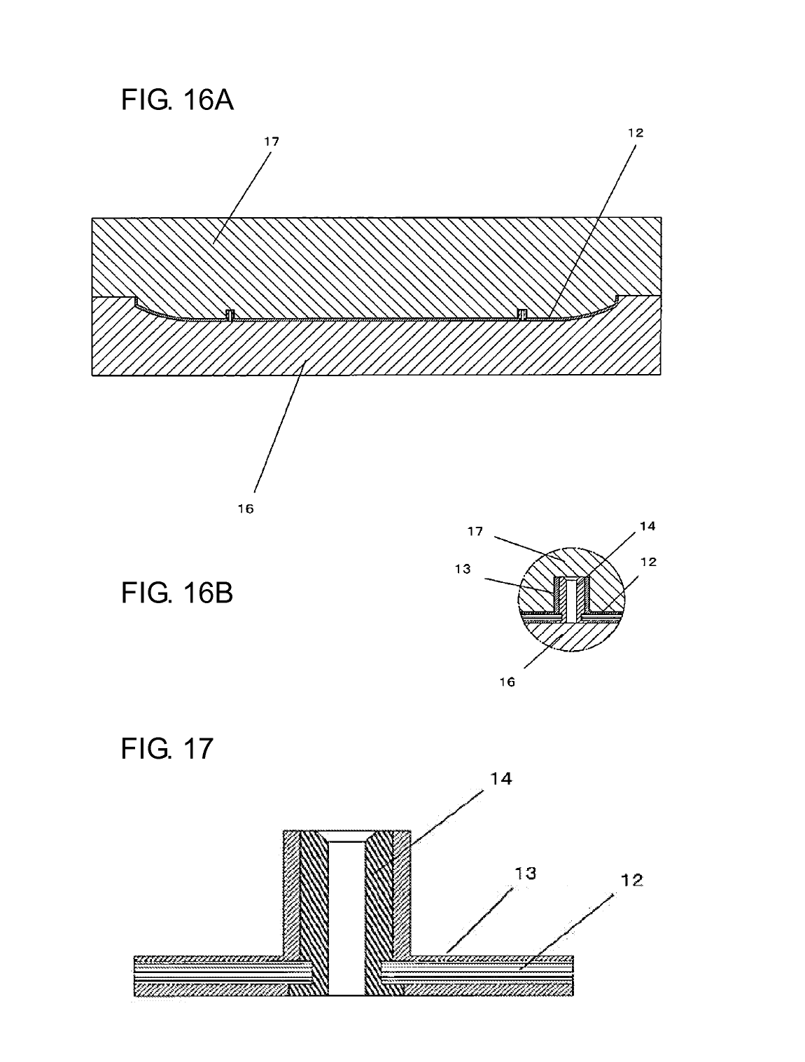

Subsequently, upper mold 17 is placed on sheet 12 as illustrated in FIGS. 15A and 15B, in which condition resin is injected into a space between lower mold 16 and upper mold 17. This injection of resin forms resin layer 13 on each of front and rear surfaces (upper and lower surfaces) of sheet 12, and on an outer circumferential portion of nut 14 as illustrated in FIGS. 16A and 16B and FIG. 17, producing a final shape of body case 4 as illustrated in FIGS. 5 through 7.

As described above, sheet 12 is in the raised state from the front surface of lower mold 16 (space-produced state) on the one end side of nut 14 (lower end side in FIG. 11) at the caulked portion in the outer circumferential direction of through hole 15 of carbon fiber sheet 12 at the time of the resin injection. Accordingly, resin smoothly flows around the outer circumference of this caulked portion.

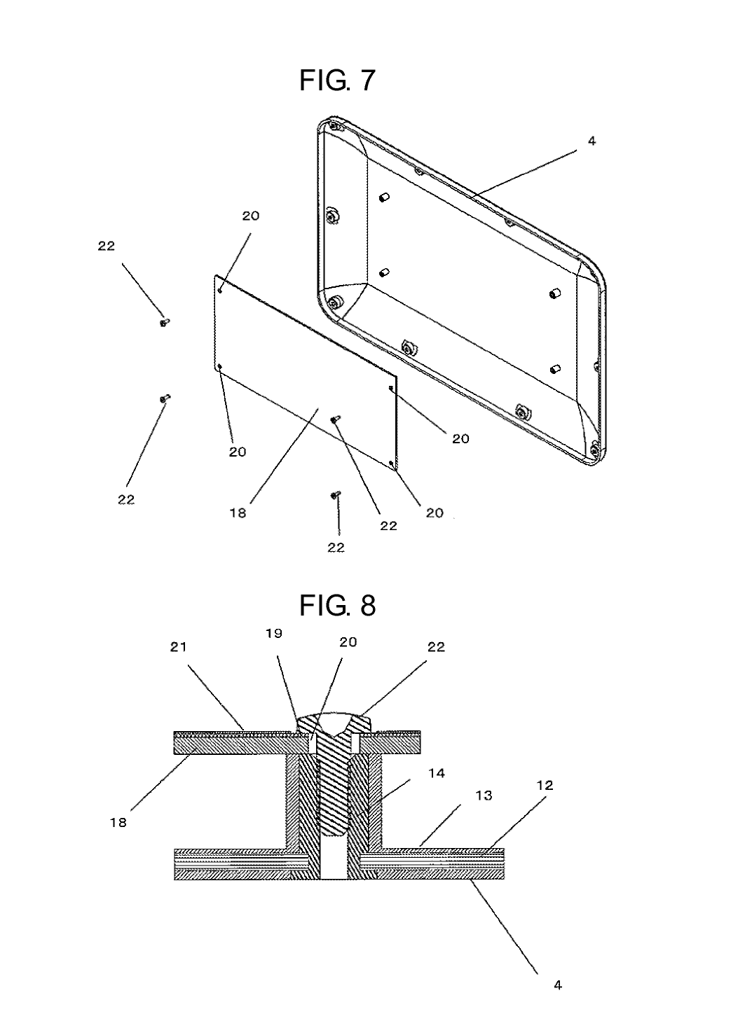

Then, electric circuit board 18 is attached to the inner surface portion of body case 4 as illustrated in FIG. 7.

Controller 7, power source unit 8, memory 9, audio output unit 10, reproduction unit 11 and others mentioned above are mounted on electric circuit board 18. Earth pattern 19 is provided on an outer periphery of electric circuit board 18 as illustrated in FIG. 8.

Each through hole 20 is formed at a portion of earth pattern 19. Resist film 21 is removed from the outer circumferential portion of through hole 20.

In this state, electric circuit board 18 illustrated in FIG. 7 is placed on (in contact with) nut 14 as illustrated in FIG. 8, whereafter conductive bolt 22 is fastened from above (on the side opposite to nut 14) toward corresponding nut 14.

In this case, threaded nut 14 may be prepared beforehand, or threads may be formed in nut 14 by insertion of bolt 22.

As a result, earth pattern 19 of electric circuit board 18 comes to electrically connect with carbon fiber sheet 12 via conductive bolt 22 and conductive nut 14 as illustrated in FIG. 8, whereby earth connection strengthens.

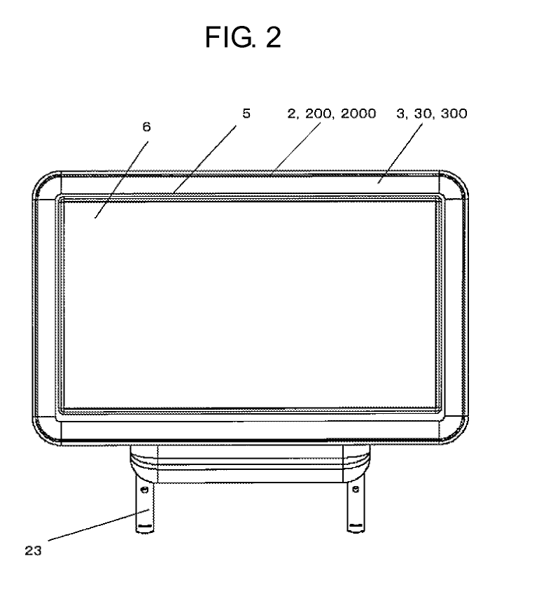

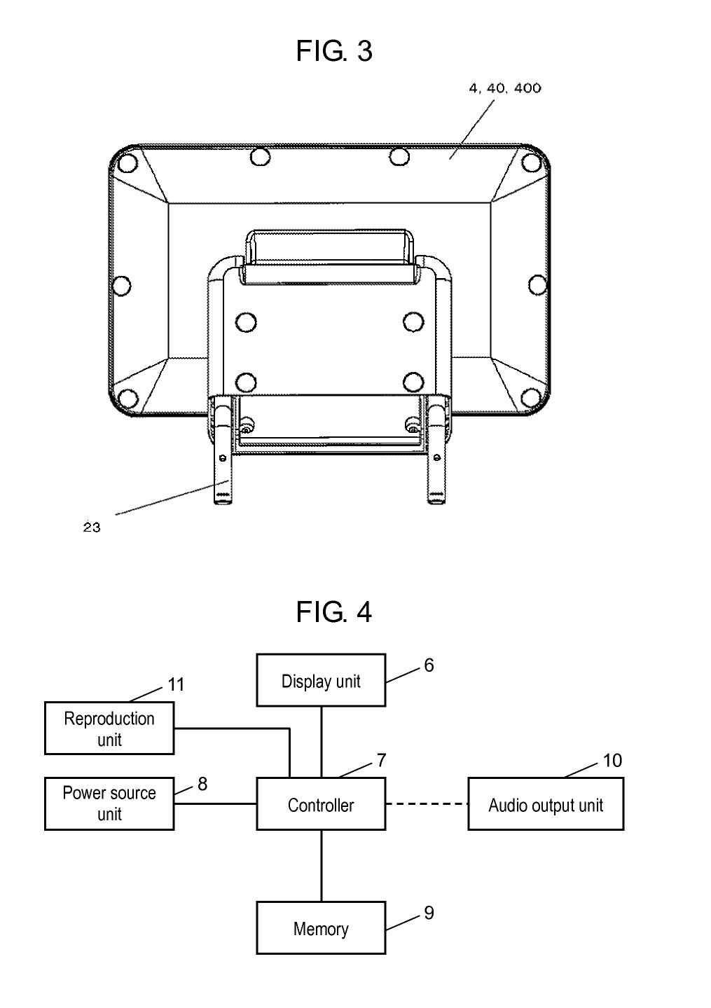

According to this exemplary embodiment, body case 4 includes body case fixtures 23 illustrated in FIGS. 2 and 3 to attach body case 4 to driver's seat 1 as illustrated in FIG. 1.

More specifically, each of body case fixtures 23 is constituted by a conductive metal pipe. An upper end side of each body case fixture 23 is inserted through a through hole (not shown) formed in body case 4 into the inside of body case 4, and electrically connected with carbon fiber sheet 12 via this insertion portion.

A lower end side of each body case fixture 23 is inserted into driver's seat 1, and attached to a metal chassis (not shown) inside driver's seat 1.

More specifically, the metal chassis inside driver's seat 1, body case fixtures 23 formed of conductive metal pipes, carbon fiber sheet 12 of body case 4, conductive nuts 14, conductive bolts 22, and earth pattern 19 of electric circuit board 18 electrically connect with each other, whereby earthing of earth pattern 19 of electric circuit board 18 strengthens.

According to this exemplary embodiment, each through hole 20 is formed at the portion of earth pattern 19. However, each through hole 20 may be disposed in a vicinity of earth pattern 19 (at a distance of contact between earth pattern 19 and bolt 22). In this case, resist film 21 is removed from the outer circumferential portion of through hole 20.

More specifically, electric circuit board 18 illustrated in FIG. 7 is similarly placed on (in contact with) nut 14 as illustrated in FIG. 8 even in this state. Then, conductive bolt 22 is fastened from above (on the side opposite to nut 14) toward corresponding nut 14.

In this case, threaded nut 14 may be prepared beforehand, or threads may be formed in nut 14 by insertion of bolt 22.

As a result, earth pattern 19 of electric circuit board 18 comes to electrically connect with carbon fiber sheet 12 via conductive bolt 22 and conductive nut 14 as illustrated in FIG. 8, whereby earth connection strengthens.

According to the first exemplary embodiment described above, a body case includes a carbon fiber sheet, a resin layer covering the sheet, and a conductive nut fixed to the sheet with caulking. An electric circuit board includes an earth pattern, and a first through hole formed in the earth pattern or in a vicinity of the earth pattern. A conductive bolt is fastened from a side opposite to the nut through the first through hole of the electric circuit board toward the nut to electrically connect the earth pattern of the electric circuit board to the body case via the nut.

Accordingly, the earth pattern of the electric circuit board comes to electrically connect with the carbon fiber sheet via the nut, whereby earth connection to the earth pattern of the electric circuit board strengthens.

### Second Exemplary Embodiment

A purpose of an invention described in a second exemplary embodiment is to prevent insufficient fixation of an electric circuit board or electric circuit part to an inner surface of a body case.

A reference number 1 in FIG. 1 indicates a driver's seat provided inside a motor vehicle, for example. Electronic apparatus 200 is provided on a rear side of driver's seat 1.

As illustrated in FIGS. 1 through 3, electronic apparatus 200 has a shape of a housing constituted by a combination of body case 30 on a front side and a body case 40 on a rear side. Display unit 6 is exposed through opening 5 formed in body case 30.

Accordingly, in case of a configuration in this exemplary embodiment, a passenger sitting on a rear seat (not shown) enjoys images shown on display unit 6.

More specifically, controller 7, power source unit 8, memory 9, audio output unit 10, and reproduction unit 11 illustrated in FIG. 4 are disposed inside body cases 30 and 40. Power source unit 8, memory 9, audio output unit 10, and reproduction unit 11 are connected with controller 7 as well as display unit 6 connected with controller 7.

As well known, reproduction unit 11 is a TV receiver, a radio receiver, or a music or image reproduction unit, for example.

Memory 9 stores operation programs or others.

Accordingly, with selection of an item to be reproduced of reproduction unit 11, an image is output to display unit 6, while a voice is output to a speaker (not shown) via audio output unit 10.

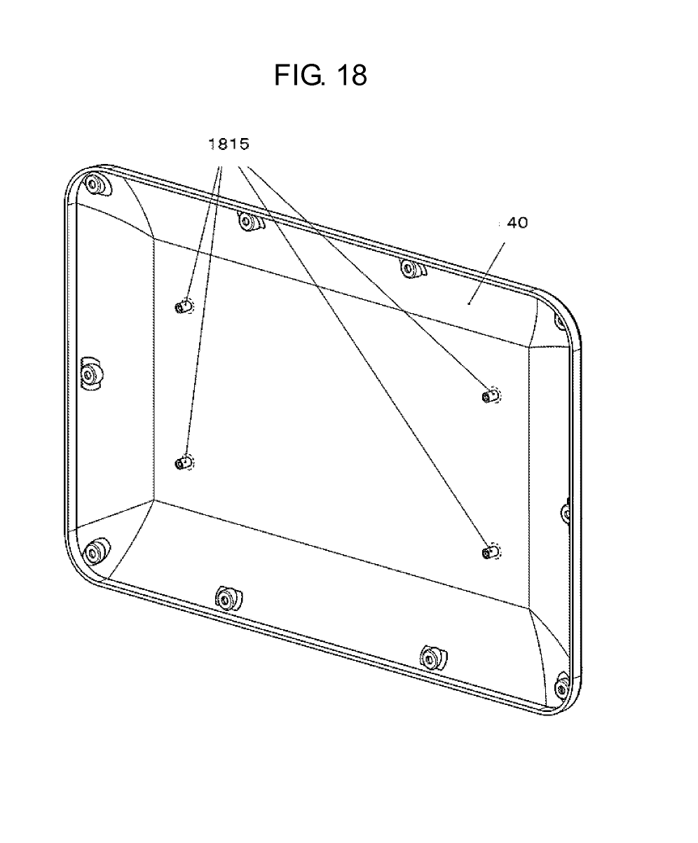

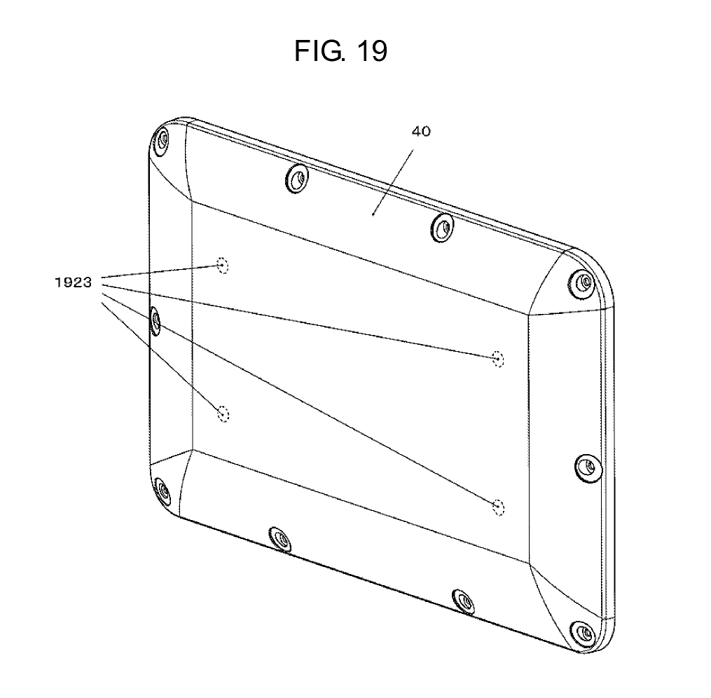

A feature of this exemplary embodiment lies in a structure of body case 40 illustrated in FIGS. 18 through 21.

More specifically, body case 40 includes carbon fiber sheet 2112, resin layer 2113 covering each of front and rear surfaces of sheet 2112, and projections 1815 formed inside body case 40 by raising a part of resin layer 2113 at portions of through holes 2114 formed in sheet 2112.

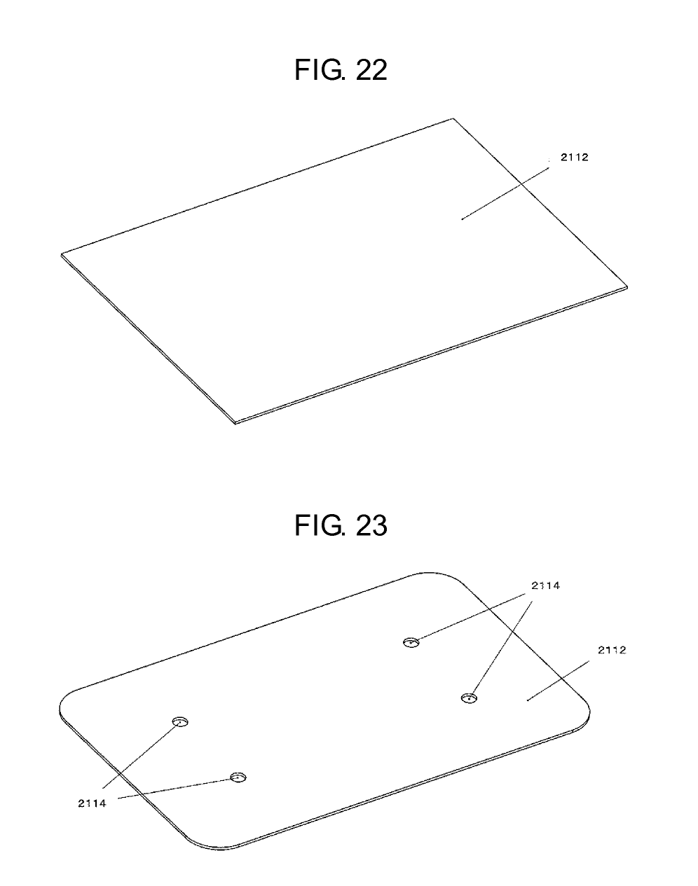

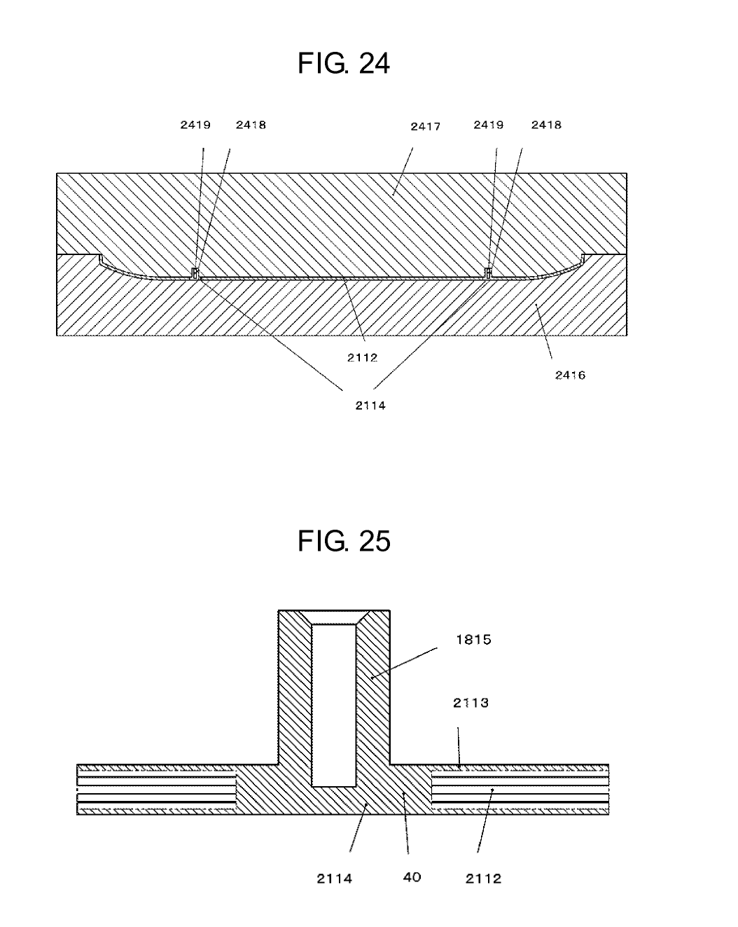

Detailed explanation further continues. At the time of manufacture of body case 40, rectangular carbon fiber sheet 2112 is initially prepared as illustrated in FIG. 22. Subsequently, through holes 2114 are formed at four positions of sheet 2112 as illustrated in FIG. 23. Then, cutting work for rounding an outer periphery of sheet 2112 is also performed. Thereafter, sheet 2112 is disposed between lower mold 2416 and upper mold 2417 as illustrated in FIG. 24, in which condition resin is injected into a space between lower mold 2416 and upper mold 2417.

In this case, portions of upper mold 2417 facing through holes 2114 of sheet 2112 include recesses 2418 each of which extends upward (in a direction opposite to lower mold 2416), and pins 2419 each of which projects downward (in a direction opposite to lower mold 2416) from a center of corresponding recess 2418 as illustrated in FIG. 24. Accordingly, projection 1815 is formed inside body case 40 as a raised part of resin layer 2113 at a portion of each through hole 2114 of sheet 2112 after completion of body case 40 as illustrated in FIG. 25.

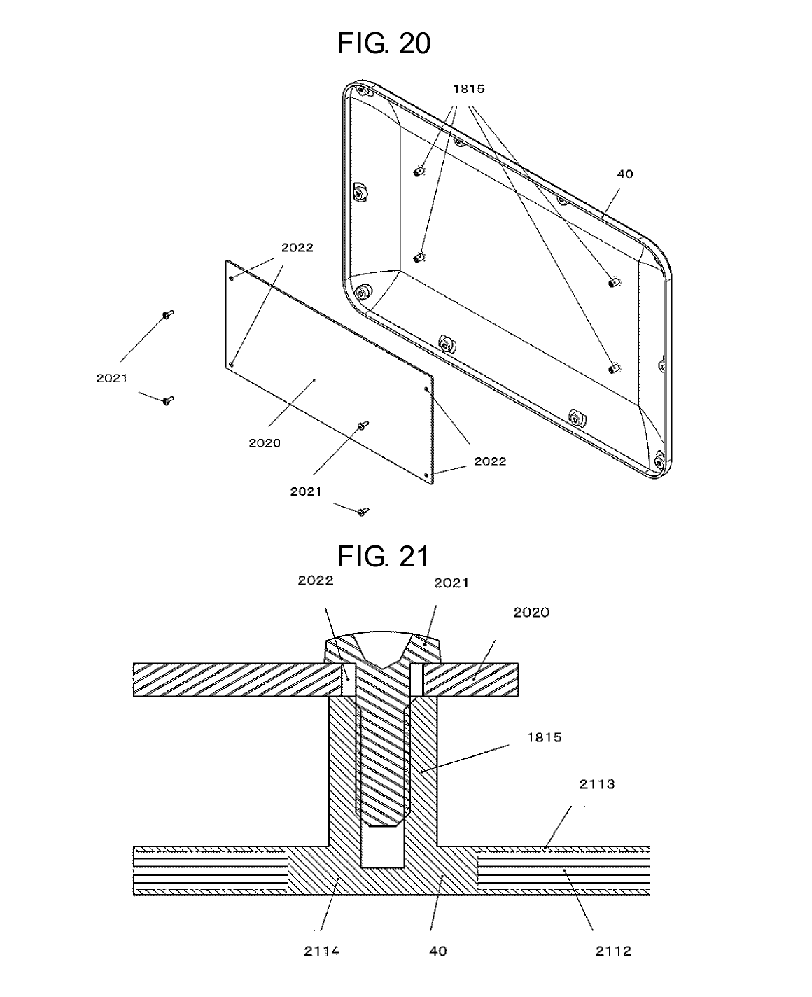

Electric circuit board 2020 to be attached inside body case 40 as illustrated in FIG. 20 is fixed to each projection 1815 by using tapping screw 2021 as illustrated in FIG. 21. Controller 7, power source unit 8, memory 9, audio output unit 10, and reproduction unit 11 mentioned above and others are mounted on electric circuit board 2020. Through holes 2022 are formed in an outer periphery of electric circuit board 2020 as illustrated in FIG. 20.

Accordingly, electric circuit board 2020 is initially placed on projections 1815 as illustrated in FIG. 20. Then, tapping screws 2021 are screwed into projections 1815 through through holes 2022 of electric circuit board 2020 from a side opposite to projections 1815. As a result, electric circuit board 2020 is fixed to portions of projections 1815.

Projections 1815 do not contain carbon fibers, wherefore tapping screws 2021 are not damaged by carbon fibers. Accordingly, electric circuit board 2020 is fixed inside body case 40 in the state illustrated in FIG. 20 in a stable manner.

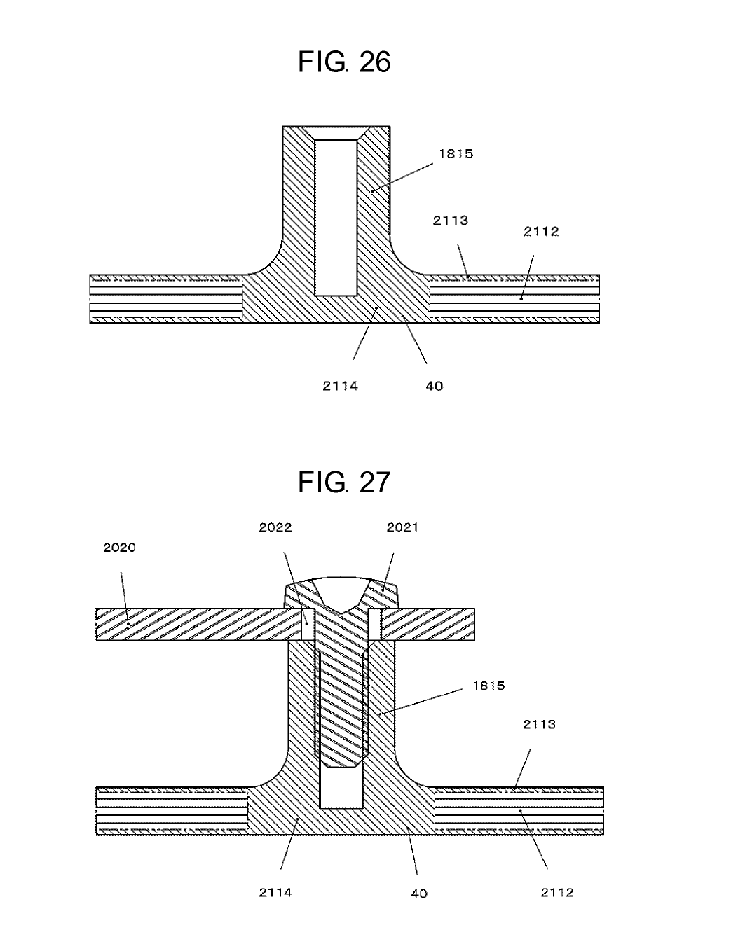

FIGS. 26 and 27 illustrate another mode (modified example) of the second exemplary embodiment. According to this mode, a thickness of resin layer 2113 is made larger in a portion of projection 1815 than in a portion of sheet 2112.

More specifically, the example illustrated in FIGS. 26 and 27 includes resin layer 2113 whose thickness gradually increases from an opening edge of through hole 2114 of sheet 2112 toward projection 1815.

This structure reduces formation of so-called sink 1923 at a portion of through hole 2114 in sheet 2112 of body case 40 on the side surface opposite to projection 1815 (front surface side), and increases strength of projection 1815.

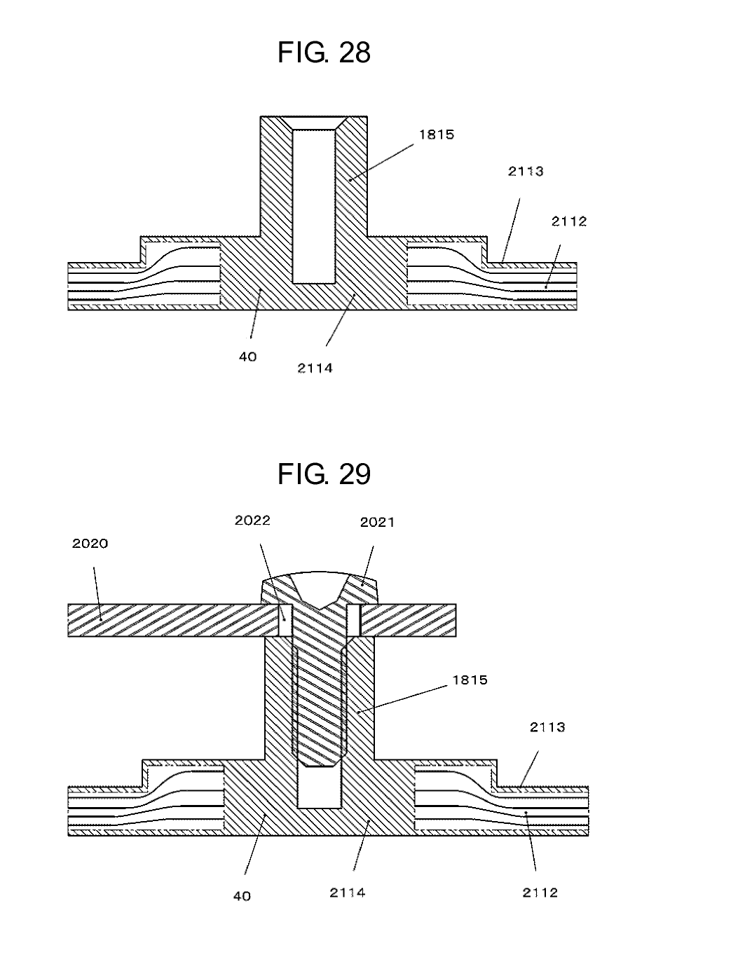

FIGS. 28 and 29 illustrate a further mode (modified example) of the second exemplary embodiment. According to this mode, the thickness of resin layer 2113 is made larger in the portion of projection 1815 than in the portion of sheet 2112 similarly to the foregoing example.

More specifically, the example illustrated in FIGS. 28 and 29 includes resin layer 2113 whose thickness is made larger in a portion outside the opening edge of through hole 2114 of sheet 2112.

This structure reduces formation of so-called sink 1923 at the portion of through hole 2114 in sheet 2112 of body case 40 on the side surface opposite to projection 1815 (front surface side), and increases strength of projection 1815.

According to the example illustrated in FIG. 28, a knitting state of carbon fibers constituting sheet 2112 in a vicinity of through hole 2114 is disentangled and expanded. In this case, strength of a base portion of projection 1815 increases.

According to the second exemplary embodiment, electric circuit board 2020 is fixed to the portions of projections 1815. However, an electric circuit part (not shown) may be fixed to the portions of projections 1815.

According to the second exemplary embodiment described above, a body case includes a carbon fiber sheet, a resin layer covering each of front and rear surfaces of the sheet, and a projection formed inside the body case by raising a part of the rein layer at a portion of a first through hole formed in the sheet. The electric circuit board or electric circuit part includes a second through hole. A tapping screw is fastened from a side opposite to the projection through the second through hole toward the projection. In this case, carbon fibers are not contained in the projection, and thus do not damage the tapping screw. Accordingly, insufficient fixation of the electric circuit board or electric circuit part to the inner surface of the body case is avoidable.

### Third Exemplary Embodiment

A purpose of an invention described in a third exemplary embodiment is to connect an antenna unit provided within a body case and a device outside the body case in such a condition that the antenna unit and the device can communicate with each other.

A reference number 1 in FIG. 1 indicates a driver's seat provided inside a motor vehicle, for example. Electronic apparatus 2000 is provided on a rear side of driver's seat 1.

As illustrated in FIGS. 1 through 3, electronic apparatus 2000 has a shape of a housing constituted by a combination of body case 300 on a front side and a body case 400 on a rear side. Display unit 6 is exposed through opening 5 formed in body case 300.

Accordingly, in case of a configuration in this exemplary embodiment, a passenger sitting on a rear seat (not shown) enjoys images shown on display unit 6.

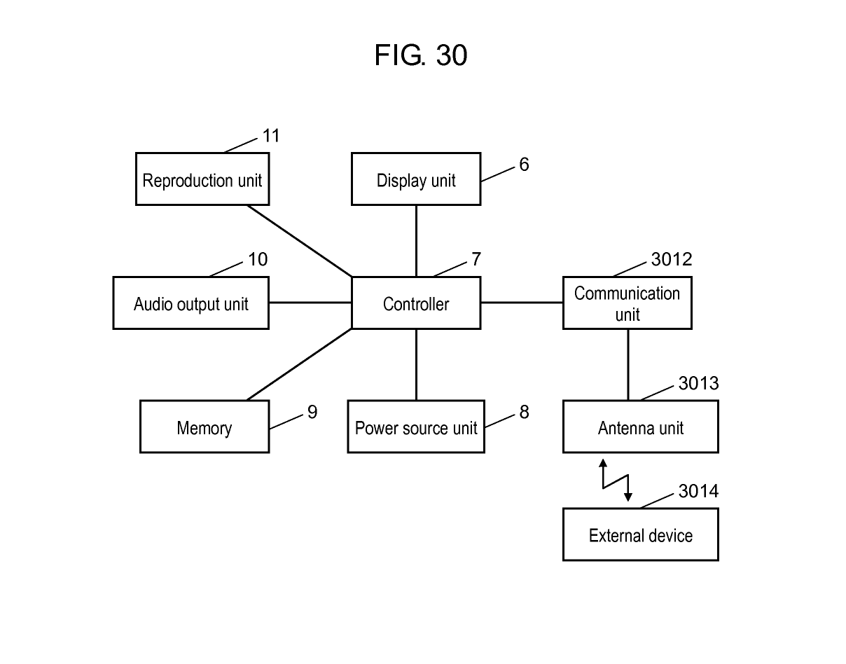

More specifically, controller 7, power source unit 8, memory 9, audio output unit 10, reproduction unit 11, communication unit 3012, and antenna unit 3013 illustrated in FIG. 30 are disposed inside body cases 300 and 400. Power source unit 8, memory 9, audio output unit 10, reproduction unit 11, and communication unit 3012 are connected with controller 7 as well as display unit 6 connected with controller 7.

Antenna unit 3013 is connected with communication unit 3012.

As well known, reproduction unit 11 is a TV receiver, a radio receiver, or a music or image reproduction unit, for example.

Memory 9 stores operation programs or others.

Accordingly, with selection of an item to be reproduced of reproduction unit 11, an image is output to display unit 6, while a voice is output to a speaker (not shown) via audio output unit 10.

Communication unit 3012 communicates with external device 3014 via antenna unit 3013 by using Wi-Fi, for example, to receive an image from external device 3014 and display the image on display unit 6, or output a voice to a speaker (not shown) via audio output unit 10.

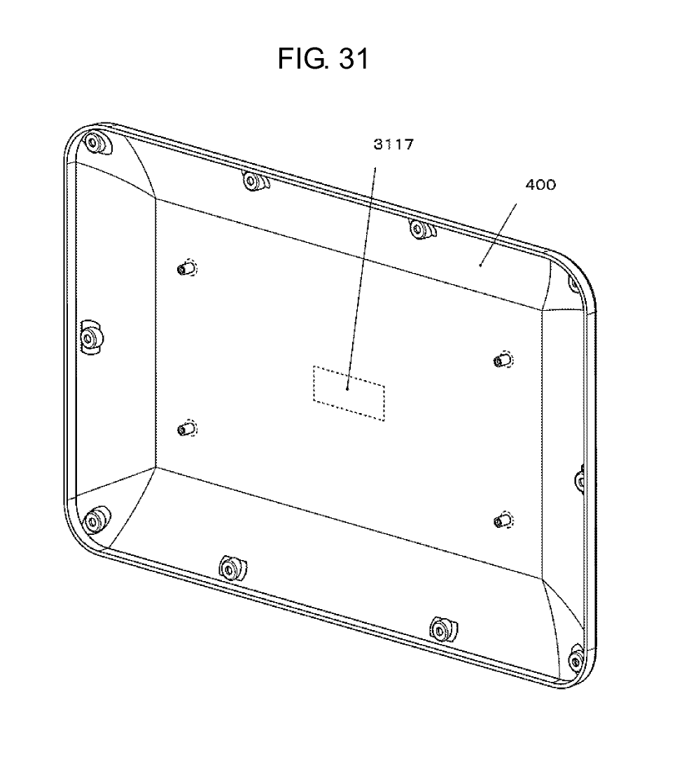

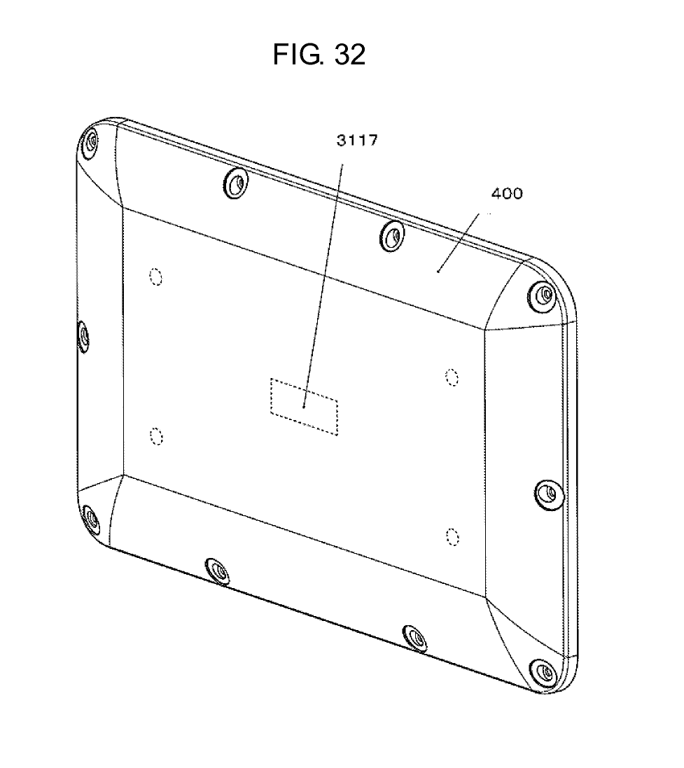

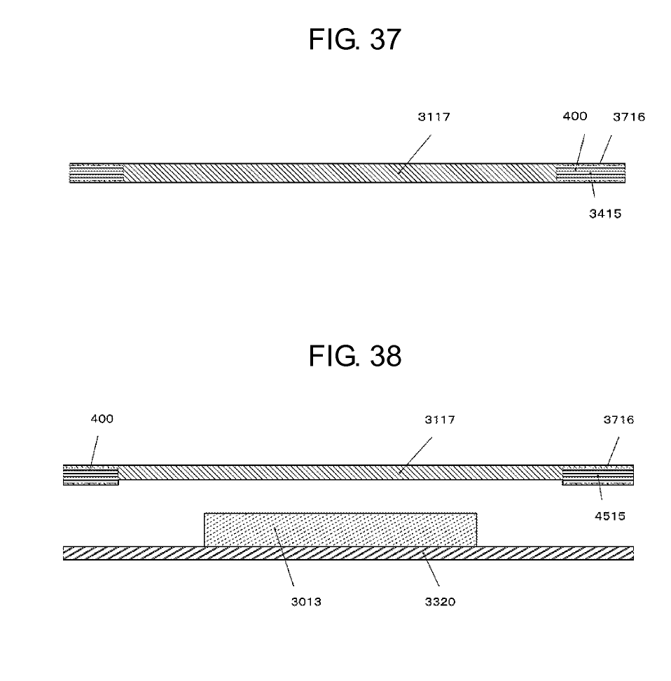

A feature of this exemplary embodiment lies in a structure of body case 400 illustrated in FIGS. 31 through 33 and FIGS. 37 and 38.

More specifically, each of body cases 300 and 400 includes carbon fiber sheet 3415, and resin layer 3716 covering each of front and rear surfaces of sheet 3415.

In this configuration, sheet 3415 of body case 4 includes opening 3117 disposed in a position facing antenna unit 3013.

Detailed explanation further continues. At the time of manufacture of body case 400, rectangular carbon fiber sheet 3415 is initially prepared as illustrated in FIG. 34. Subsequently, opening 3117 is formed in sheet 3415 as illustrated in FIG. 35. In addition, cutting work for rounding an outer periphery of sheet 3415 is performed.

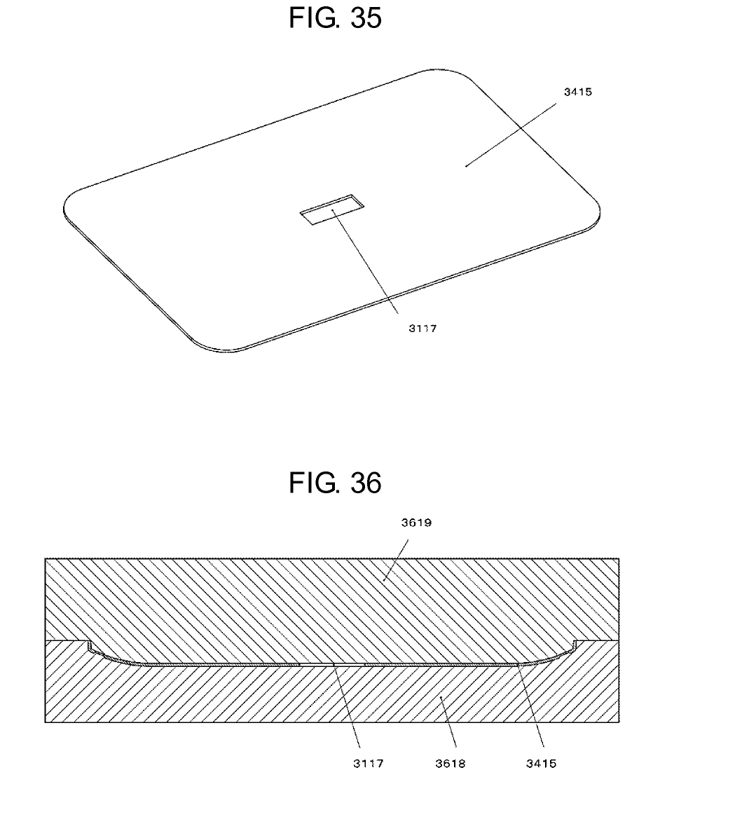

Thereafter, sheet 3415 is disposed between lower mold 3618 and upper mold 3619 as illustrated in FIG. 36, in which condition resin is injected into a space between lower mold 3618 and upper mold 3619. As illustrated in FIGS. 35 and 38, this injection of resin forms resin layer 3716 on each of front and rear surfaces (upper and lower surfaces) of sheet 3415, and inside opening 3117, producing a final shape of body case 400 illustrated in FIGS. 31 through 33.

Concerning body case 300, resin layer 3716 is formed on each of front and rear surfaces of sheet 3415 which includes opening 5 formed for display unit 6. In this case, resin layer 3716 is not provided on a portion of opening 5.

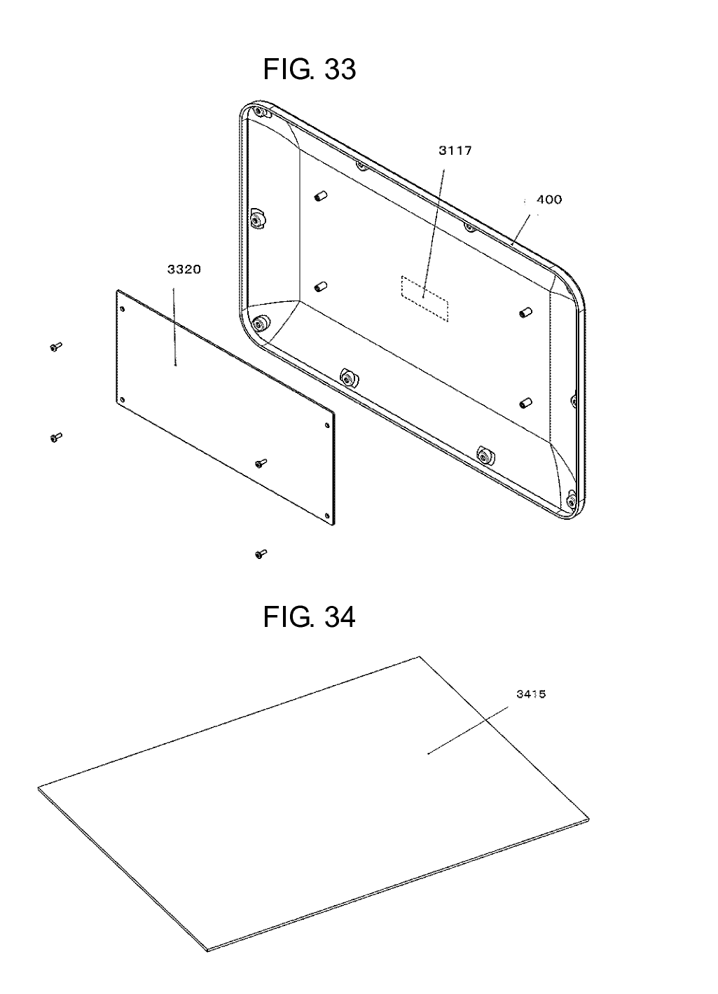

Then, electric circuit board 3320 is attached to an inner surface portion of body case 400 as illustrated in FIGS. 33 and 38.

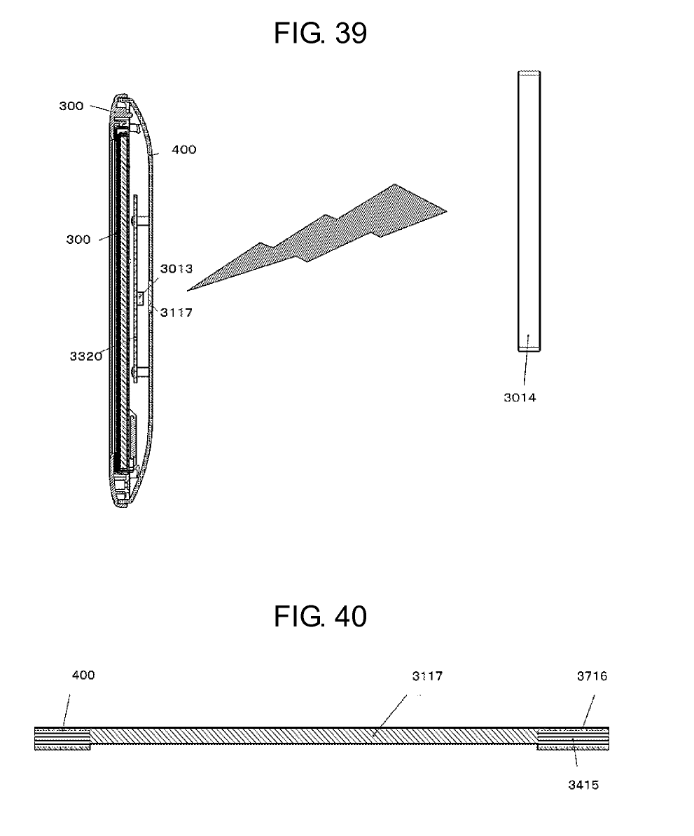

Controller 7, power source unit 8, memory 9, audio output unit 10, reproduction unit 11, communication unit 3012, and antenna unit 3013 mentioned above and others are mounted on electric circuit board 3320. In this configuration, antenna unit 3013 is mounted in such a condition as to face opening 3117 of sheet 3415 as illustrated in FIGS. 38 and 39.

More specifically, communication with external device 3014 is achieved via antenna unit 3013. In this case, a portion of body case 4 facing antenna unit 3013 corresponds to opening 3117 where carbon fiber sheet 3415 constituting body case 4 is not present. Accordingly, electronic apparatus 2 and external device 3014 are allowed to communicate with each other through opening 3117.

Moreover, resin layer 3716 covering opening 3117 prevents entrance of dust or the like into body case 400.

Furthermore, the presence of carbon sheet 3415 in body cases 400 and 300 in areas other than opening 3117 increases strength of body cases 400 and 300.

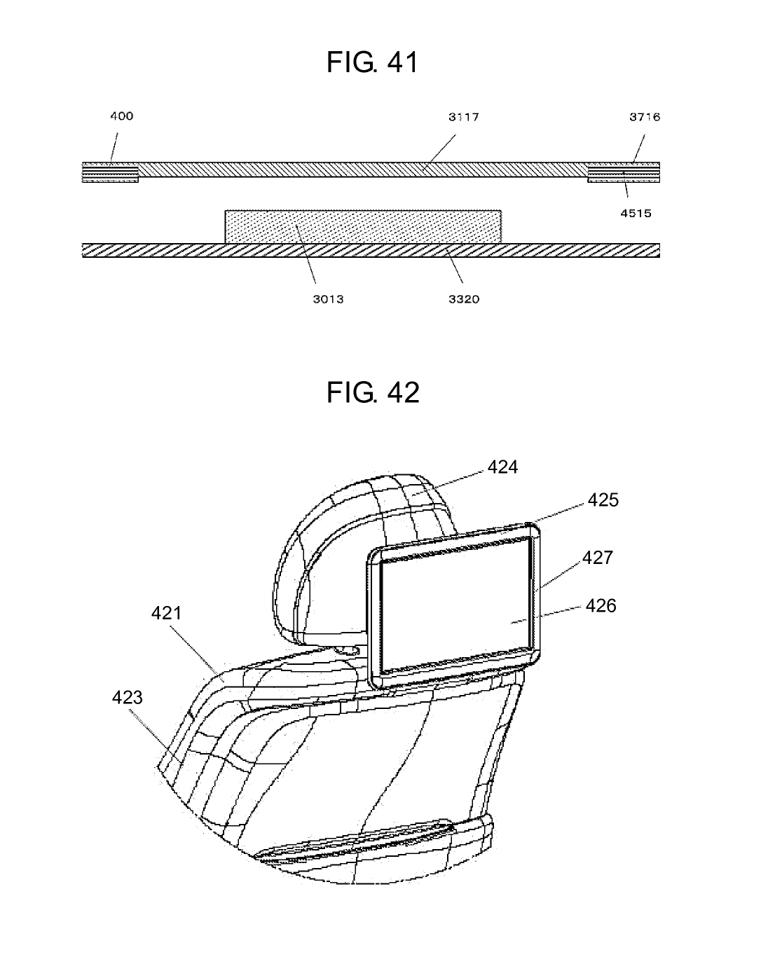

FIGS. 40 and 41 illustrate another mode (modified example). According to this mode, a thickness of body case 4 is made smaller in a portion of opening 3117 of sheet 3415 than in an outer circumferential portion of opening 3117 of sheet 3415.

More specifically, resin layer 3716 is thinner in the portion of opening 3117 of sheet 3415. In this case, receiving sensitivity of antenna unit 3013 is allowed to increase by reduction of the thickness of resin layer 3716 when the receiving sensitivity of antenna unit 3013 is low depending on types of resin layer 3716.

According to the third exemplary embodiment as described above, a body case includes a carbon fiber sheet, and a resin layer covering the sheet. The electric circuit board includes a communication unit, and an antenna unit connected with the communication unit. According to this configuration, an opening is formed in the sheet in a portion facing the antenna unit. The resin layer is formed inside the opening.

In this case, the opening of the sheet constituting body case becomes an area containing no carbon fiber. Accordingly, the antenna unit facing this area is allowed to communicate with a device outside the body case.

### Fourth Exemplary Embodiment

A display device, and a mobile device equipped with the display device according to a fourth exemplary embodiment are hereinafter described with reference to the drawings.

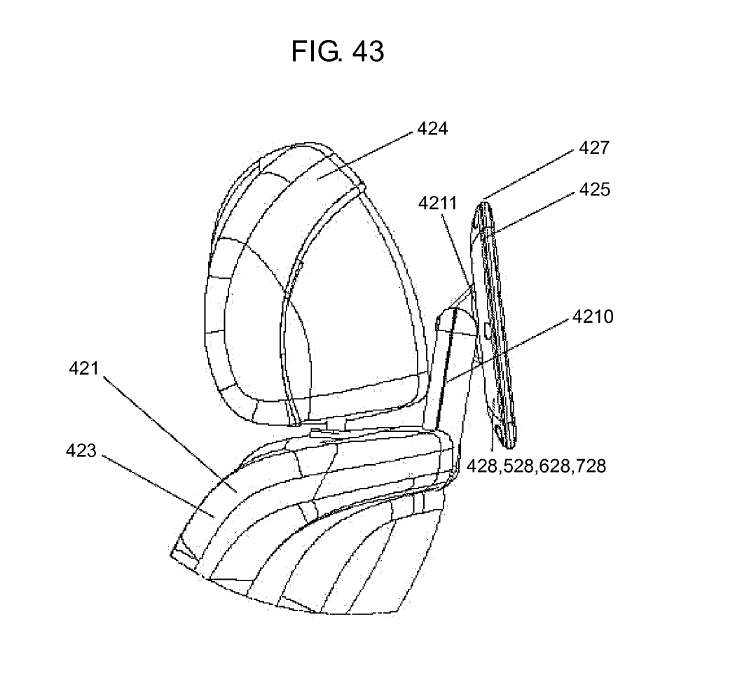

A reference number 421 in FIGS. 42 and 43 indicates a front seat of a motor vehicle, such as a driver's seat or an assistant driver's seat.

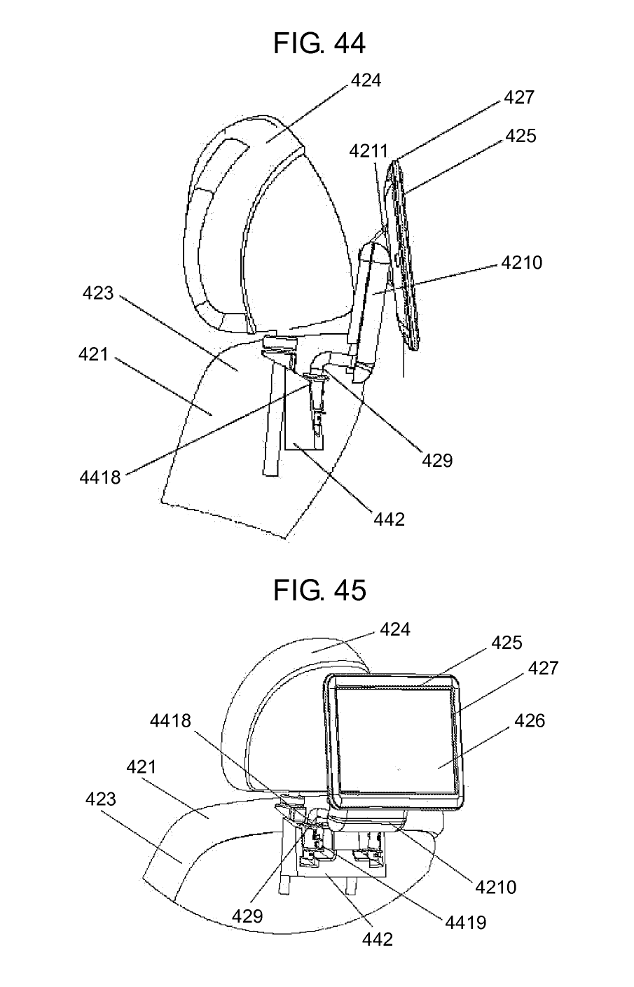

Front seat 421 includes metal seat constituent 442 a part of which is illustrated in FIGS. 44 and 45, cover member 423 covering seat constituent 442, and head restraint 424 provided on cover member 423.

A feature of the fourth exemplary embodiment lies in a point that display device 425 is attached to an upper rear side of front seat 421 by utilizing metal seat constituent 442.

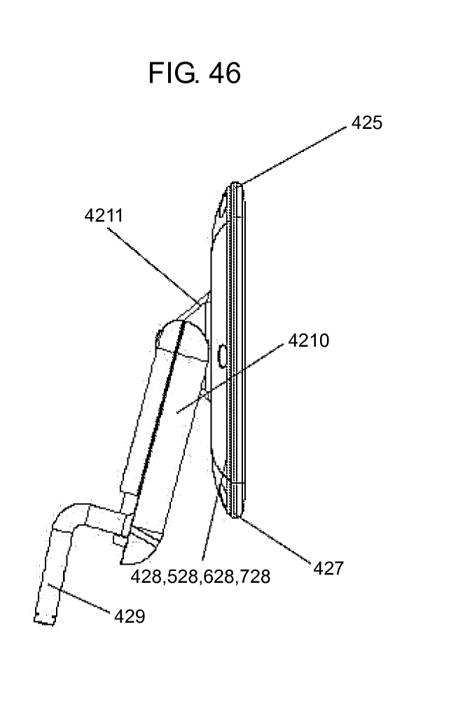

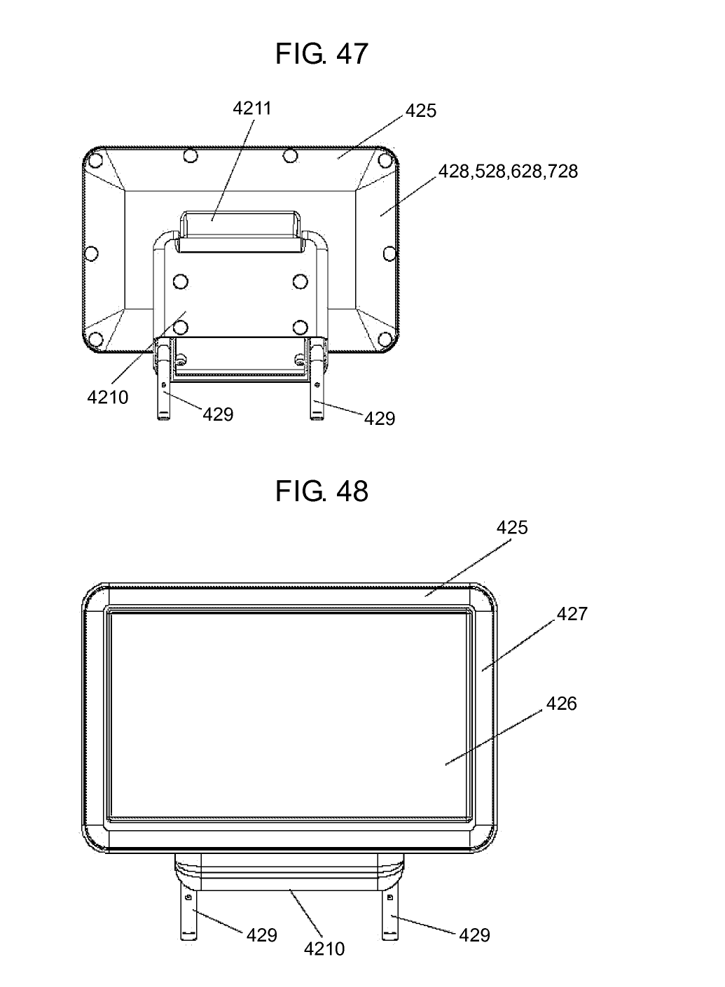

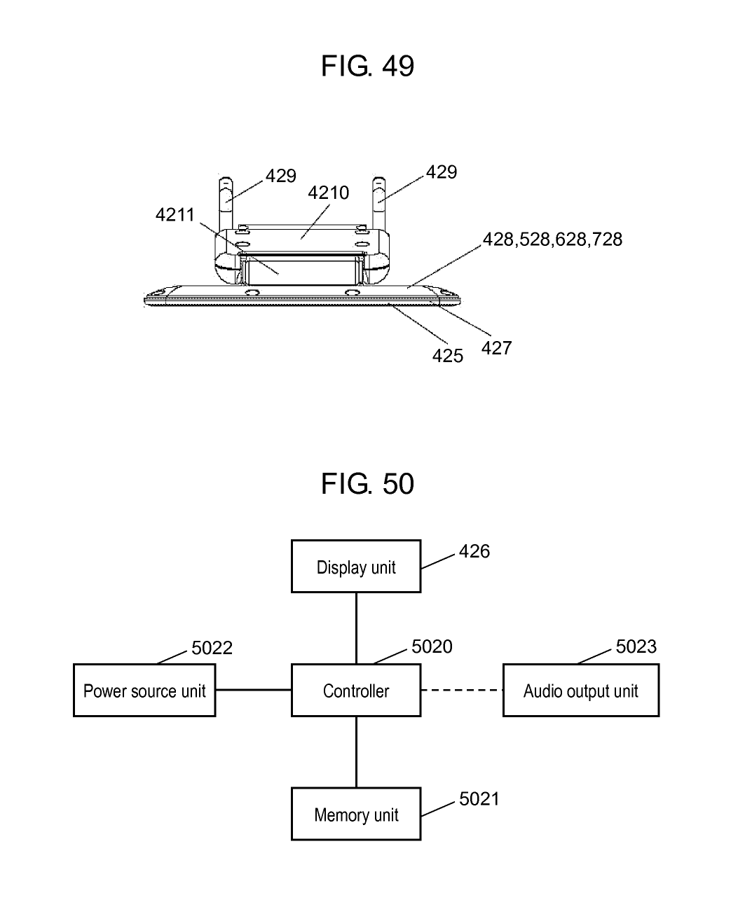

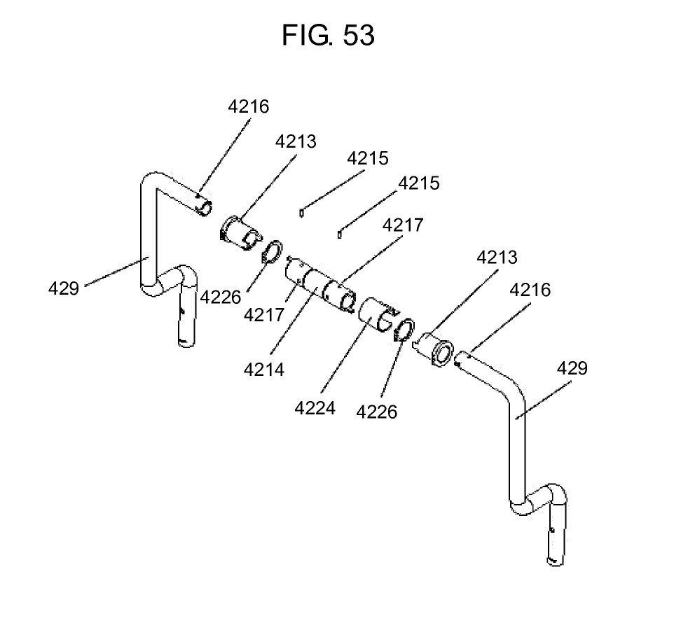

As can be understood from FIGS. 46 through 49, display device 425 includes display unit 426 provided in a direction from an upper rear side of front seat 421 toward the rear, cover 427 covering an outer peripheral side of display unit 426, cover 428 covering a rear side (front seat 421 side) of display unit 426, two cylindrical (or bar-shaped) attachment shafts 429 for attaching cover 428 to seat constituent 442 as illustrated in FIG. 53, and cover 4210 covering two attachment shafts 429 as a part of cover 428.

Each of covers 427, 428, and 4210 is made of carbon fiber reinforced plastics (Carbon Fiber Reinforced Plastics).

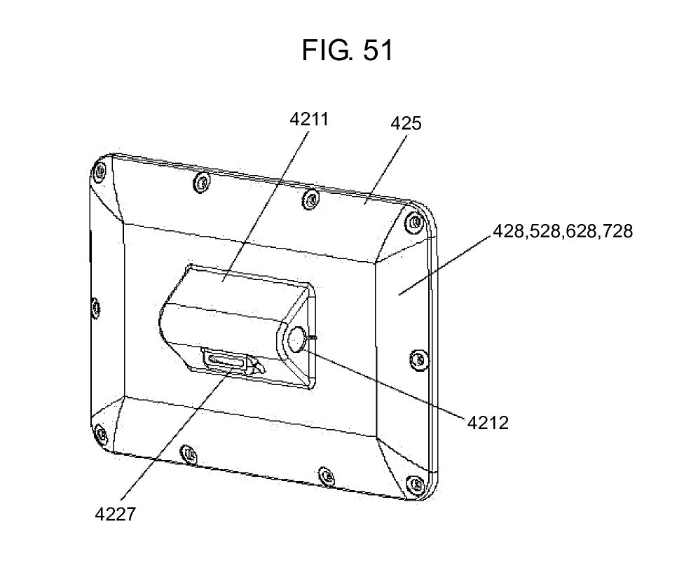

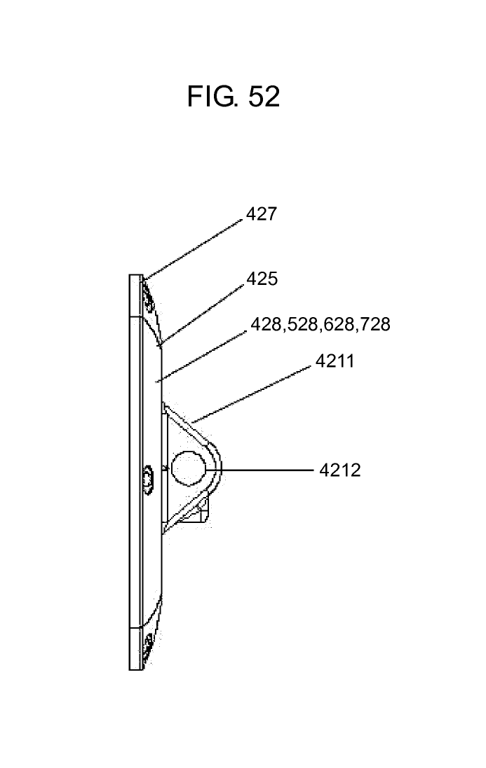

In this configuration, protruding portion 4211 protruding toward the rear is provided on a rear side (front seat 421 side) of cover 428 as illustrated in FIGS. 51 and 52. In addition, insertion hole 4212 is provided on each of opposed parts of protruding portion 4211, as a through hole through which a part, i.e., an upper end of corresponding attachment shaft 429 is inserted.

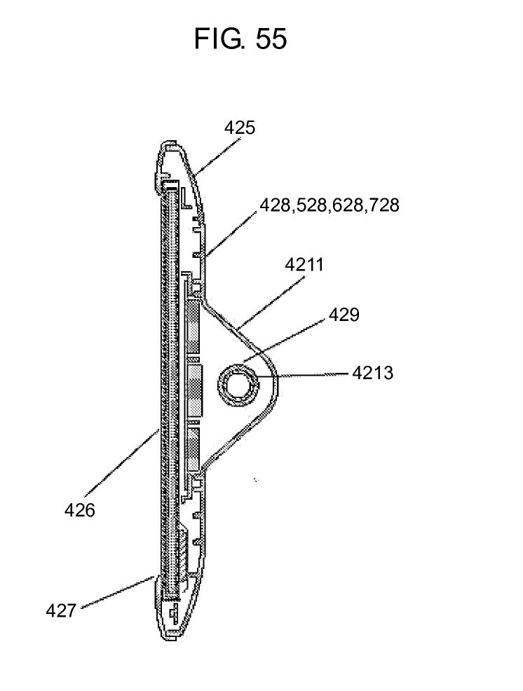

Moreover, cylindrical bearing 4213 illustrated in FIGS. 53 and 55 is attached to each of insertion holes 4212.

Each upper end of two attachment shafts 429 is inserted into cover 428 through a through hole of corresponding bearing 4213.

As can be understood from FIG. 53, the upper ends of two attachment shafts 429 are connected with each other via cylindrical connecting fitting 4214 inside cover 428 by insertion of the upper ends of two attachment shafts 429 into connecting fitting 4214, and further by insertion of pins 4215 into through holes 4216 of attachment shafts 429 and through holes 4217 of connecting fitting 4214.

This assembly is performed in a state of removal of cover 427 from cover 428.

On the other hand, lower ends of two attachment shafts 429 are inserted into cover member 423 through openings 4418 of cover member 423, and fixed inside cover member 423 by using seat constituent 442, attachment screws 4419 and others, as can be understood from FIGS. 44 and 45.

According to the configuration described above, display device 425 is securely attached via two attachment shafts 429 to metal seat constituent 442 constituting front seat 421 on the rear side of front seat 421 as illustrated in FIGS. 42 through 45.

In this state, display unit 426 is oriented toward a rear seat side, wherefore display unit 426 is viewable from the rear seat side.

More specifically, display device 425 includes controller 5020 which contains display unit 426, memory unit 5021, power source unit 5022, and audio output unit 5023 as illustrated in FIG. 50. Accordingly, an image or a voice recorded on memory unit 5021, for example, is viewable or hearable from the rear seat side.

At the time of viewing and hearing, adjustment of a tilt of display unit 426, i.e., so-called tilt adjustment is easily made with a hold of display unit 426.

More specifically, according to a structure of this exemplary embodiment, upper ends of two attachment shafts 429 are inserted into the through holes of bearings 4213. Accordingly, the tilt adjustment of display unit 426 is easily achievable around bearings 4213.

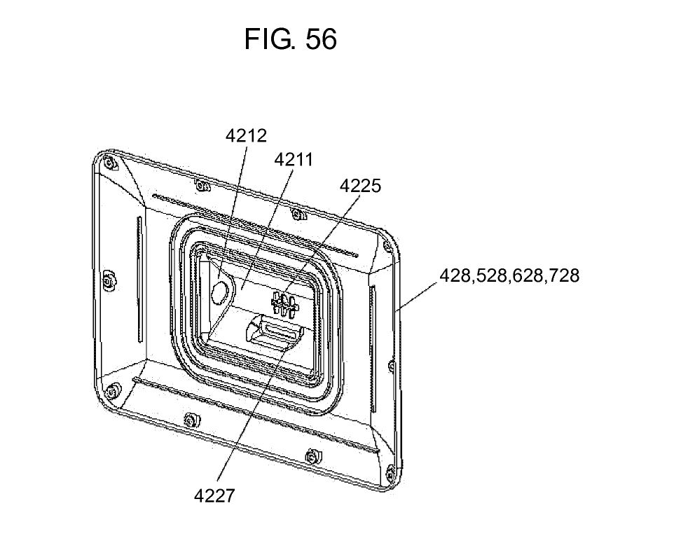

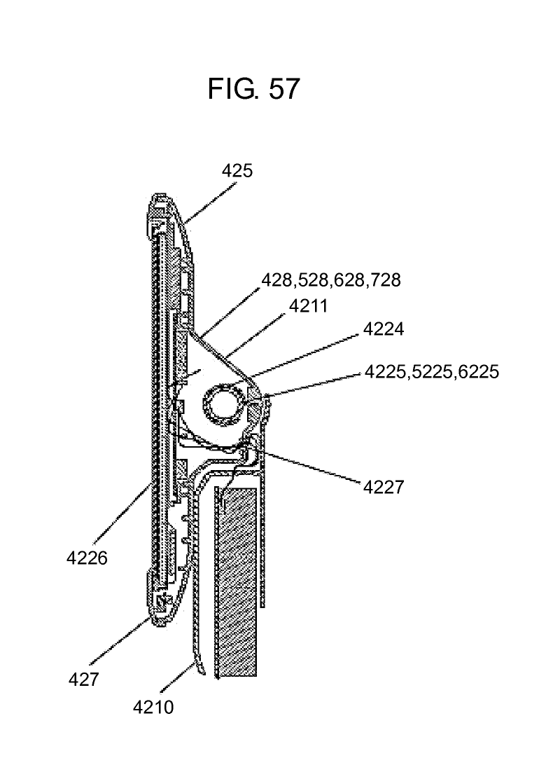

Moreover, according to this exemplary embodiment, C-shaped tension member 4224 made of elastic material is brought into contact with an outer circumference of connecting fitting 4214 to apply appropriate tension to rotation of display unit 426 as can be understood from FIGS. 53, 56, and 57. An end of tension member 4224 is inserted into attachment portion 4225 of cover 428 and fixed to attachment portion 4225.

Rings 4226 illustrated in FIG. 53 are movement prevention rings for preventing large movement of tension member 4224 leftward and rightward along an outer circumference of connecting fitting 4214. Rings 4226 are fixed to left and right bearings 4213, respectively.

As can be understood from FIGS. 51, 56 and 57, opening 4227 is formed in a lower part of protruding portion 4211 of cover 428, as an opening through which respective wirings are drawn out.

Metal seat constituent 442 according to this exemplary embodiment acts as an earth of a motor vehicle. In this case, covers 428 and 427 are earthed via metal attachment shafts 429 fixed to seat constituent 442, metal connecting fitting 4214 connected with attachment shafts 429, and metal tension member 4224 in contact with connecting fitting 4214. Accordingly, noise effect on electronic parts disposed within covers 427 and 428 considerably improves.

More specifically, covers 427 and 428 each made of carbon fiber reinforced plastics have conductivity, wherefore earth connection of covers 427 and 428 through a route mentioned above realizes considerable improvement of noise effect on the electronic parts disposed within covers 427 and 428.

Each of covers 427 and 428 made of carbon fiber reinforced plastics has considerably high strength, and a light weight. Accordingly, a sense of discomfort given from covers 427 and 428 decreases even when covers 247 and 428 are attached to the upper rear side of front seat 421 as illustrated in FIGS. 42 and 43.

Furthermore, the considerably high strength and reduced weight increase a size of display unit 426.

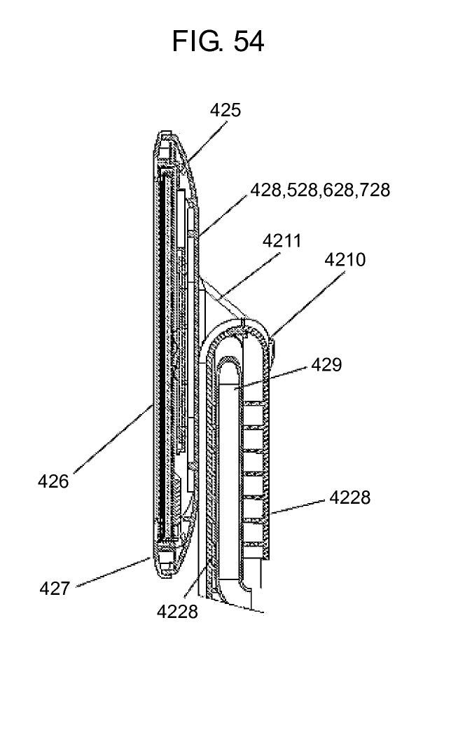

As illustrated in FIG. 54, rib 4228 for positioning attachment shafts 429 is provided on cover 4210. Accordingly, appropriate positioning of attachment shafts 429 is achievable.

The display device according to the fourth exemplary embodiment includes a display unit, a cover covering an outer peripheral side or a rear side of the display unit, and cylindrical or bar-shaped attachment shafts that attach the cover to a seat constituent. The cover is made of carbon fiber reinforced plastics. The cover includes insertion holes through each of which a part of the corresponding attachment shaft is inserted into the cover. A cylindrical bearing is attached to each of the insertion holes. A part of each of the attachment shafts is inserted through a through hole of a corresponding bearing into the cover. Accordingly, damage to the cover or the attachment shafts is avoidable.

More specifically, according to the display device in the fourth exemplary embodiment, the cover includes insertion holes through each of which a part of the corresponding attachment shaft is inserted into the cover. The cylindrical bearing is attached to each of the insertion holes. A part of each of the attachment shafts is inserted into the cover through the through hole of the corresponding bearing. In this case, the insertion holes of the cover made of carbon fiber reinforced plastics do not rub against the attachment shafts at the time of adjustment of a tilt of the display unit, i.e., so-called tilt adjustment. Accordingly, damage to the cover or the attachment shafts is avoidable.

### Fifth Exemplary Embodiment

A display device, and a mobile device equipped with the display device according to a fifth exemplary embodiment are hereinafter described with reference to the drawings. Explanation similar to the explanation of the fourth exemplary embodiment concerning FIGS. 42 through 57 is not repeated herein.

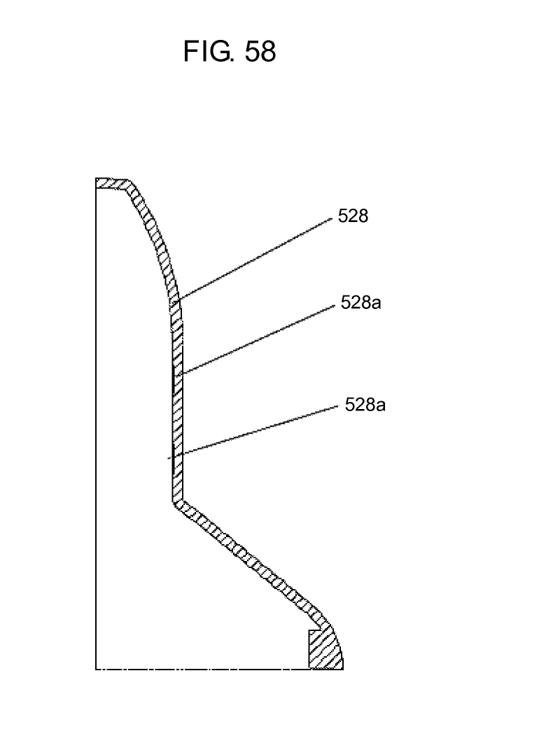

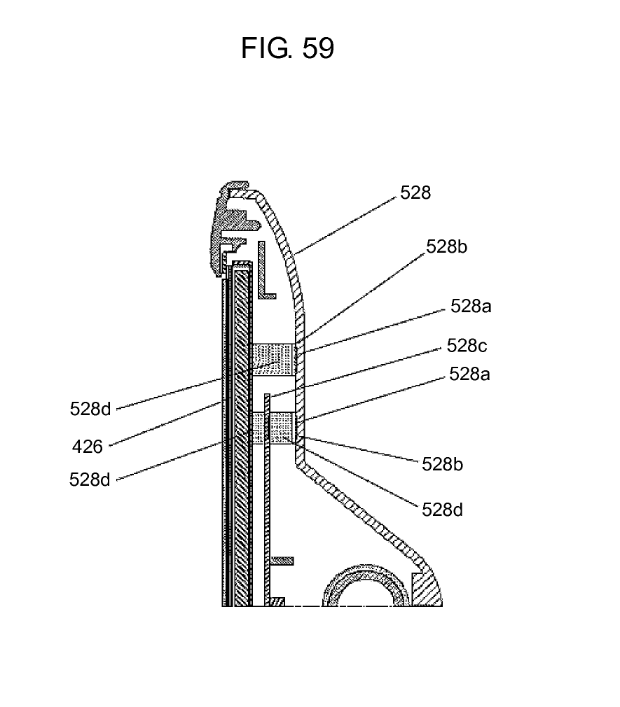

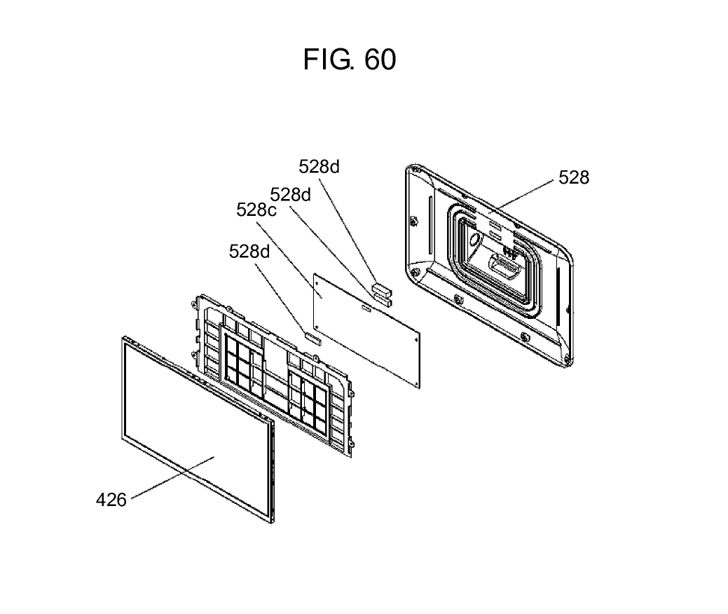

According to the fifth exemplary embodiment, carbon fiber exposure portions 528a are formed by cutting an inner surface of cover 528 as illustrated in FIG. 58. Each exposure portion 528a is covered with conductive tape 528b (whose area is larger than the area of exposure portion 528a) as illustrated in FIG. 59.

In addition, each of conductive tapes 528b is electrically connected, via conductor 528d constituted by conductive foam, to an earth line (not shown) of display unit 426, or an earth line (not shown) of control board (constituting a circuit other than display unit 426 in FIG. 50) 528c.

Accordingly, earth connection is made, via cover 528, between the earth line of display unit 426 or the earth line of control board 528c, and conductor 528d, conductive tapes 528b, carbon fiber exposure portions 528a, cover 528, tension member 4224, connecting fitting 4214, attachment shafts 429, and metal seat constituent 442.

This earth connection requires conduction between the end of tension member 4224 and carbon fibers constituting cover 528 at the time of insertion of the end of tension member 4224 into attachment portion 5225 of cover 528 (Alternatively, connection may be made between metal seat constituent 442 and different exposure portion 528a formed outside cover 528).

More specifically, cover 528 contains carbon fiber reinforced plastics (Carbon Fiber Reinforced Plastics) and carbon fibers therein have conductivity. Accordingly, earth connection is made, via cover 528, between metal seat constituent 442 and the earth line of display unit 426 or the earth line of control board 528c based on electric connection, via conductor 528d, between the earth line of display unit 426 or the earth line of control board 528c and conductive tapes 528b which cover carbon fiber exposure portions 528a formed on the inner surface of cover 528.

Moreover, fiber carbon reinforced plastics have characteristics of high strength and high elasticity. Accordingly, even when deformation of fiber carbon reinforced plastics is large under application of force, a deformed state returns to the original state with removal of the force. Even in such a case, conductive powder of carbon fibers does not scatter into cover 528 from carbon fiber exposure portions 528a of cover 528 in a state that carbon fiber exposure portions 528a are covered with conductive tapes 528b (which are generally more elastic than carbon fiber reinforced plastics). Accordingly, electric problems caused by conductive powder are avoidable.

The display device according to the fifth exemplary embodiment described above offers following advantages as well as the advantages provided by the fourth exemplary embodiment.

The display device according to the fifth exemplary embodiment includes carbon fiber exposure portions on the inner surface of the cover. The exposure portions are covered with conductive tapes. The conductive tapes are electrically connected via a conductor to at least either an earth line of the display unit or an earth line of a control board. Accordingly, earth connection of at least either the earth line of the display unit or the earth line of the control board is made via the cover.

Moreover, according to the display device of the fifth exemplary embodiment, the carbon fiber exposure portions of the cover are covered with the conductive tapes. In this case, carbon fiber conductive powder does not scatter from the carbon fiber exposure portions into the cover. Accordingly, electric problems caused by conductive powder are avoidable.

### Sixth Exemplary Embodiment

A display device, and a mobile device equipped with the display device according to a sixth exemplary embodiment are hereinafter described with reference to the drawings. Explanation similar to the explanation of the fourth exemplary embodiment concerning FIGS. 42 through 57 is not repeated herein.

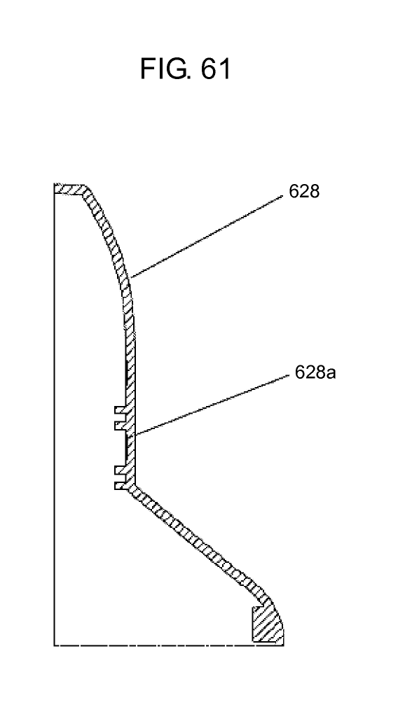

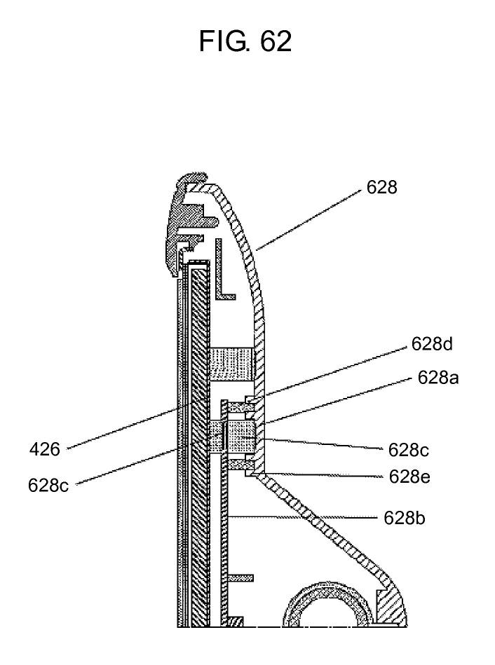

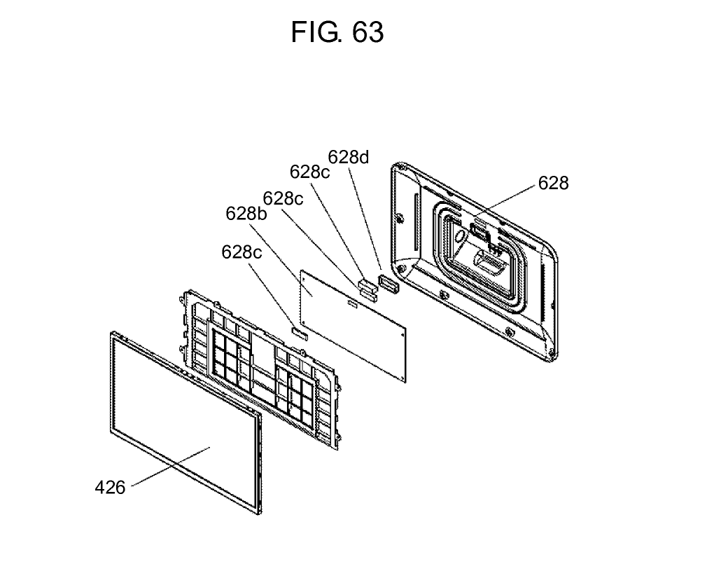

According to the sixth exemplary embodiment, carbon fiber exposure portion 628a is formed by cutting an inner surface of cover 628 as illustrated in FIG. 61. As illustrated in FIGS. 62 and 63, exposure portion 628a is electrically connected, via conductor 628c made of conductive foam, to the earth line (not shown) of display unit 426, or the earth line (not shown) of control board (constituting a circuit other than display unit 426 in FIG. 50) 628b.

Accordingly, earth connection is made, via cover 628, between the earth line of display unit 426 or the earth line of control board 628b and conductor 628c, carbon fiber exposure portion 628a, cover 628, tension member 4224, connecting fitting 4214, attachment shafts 429, and metal seat constituent 442.

This earth connection requires conduction between the end of tension member 4224 and carbon fibers constituting cover 628 at the time of insertion of the end of tension member 4224 into attachment portion 6225 of cover 628 (Alternatively, connection may be made between metal seat constituent 442 and different exposure portion 628a formed outside cover 628).

More specifically, cover 628 contains carbon fiber reinforced plastics (Carbon Fiber Reinforced Plastics) and carbon fibers therein have conductivity. Accordingly, earth connection is made, via cover 628, between metal seat constituent 442 and the earth line of display unit 426 or the earth line of control board 628c based on electric connection, via conductor 628c, between the earth line of display unit 426 or the earth line of control board 628c and carbon fiber exposure portion 628a formed on the inner surface of cover 628.

Moreover, fiber carbon reinforced plastics have characteristics of high strength and high elasticity. Accordingly, even when deformation of fiber carbon reinforced plastics is large under application of force, a deformed state returns to the original state with removal of the force. Even in such a case, conductive powder of carbon fibers does not scatter into cover 628 from carbon fiber exposure portion 628a of cover 628 covered with cylindrical packing 628d (which is generally more elastic than carbon fiber reinforced plastics) provided around an outer circumference of exposure portion 628a. Accordingly, electric problems caused by conductive powder are avoidable.

According to the sixth exemplary embodiment, conductor 628c is made of conductive foam. In this case, reliability of conductivity increases when a compression state is produced between a surface of exposure portion 628a and display unit 426 or control board 628b.

More specifically, frame 628e for receiving one end side of packing 628d is provided on an outer circumference of carbon fiber exposure portion 628a of cover 628 according to this exemplary embodiment, so that conductor 628c as a flexible component can be attached to the outer circumference of exposure portion 628a in an appropriate manner.

The display device according to the sixth exemplary embodiment described above offers following advantages as well as the advantages provided by the fourth exemplary embodiment.

The display device according to the sixth exemplary embodiment includes a carbon fiber exposure portion on the inner surface of the cover. The exposure portion is electrically connected via a conductor to at least either an earth line of the display unit or an earth line of a control board. In addition, an outer circumference of the carbon fiber exposure portion of the cover is covered with the packing. Accordingly, earth connection of at least either the earth line of the display unit or the earth line of the control board is made via the cover.

Moreover, outer circumference of the carbon fiber exposure portion of the cover is covered with the packing. In this case, carbon fiber conductive powder does not scatter from the carbon fiber exposure portion into the cover. Accordingly, electric problems caused by conductive powder are avoidable.

### Seventh Exemplary Embodiment

A display device, and a mobile device equipped with the display device according to a seventh exemplary embodiment are hereinafter described with reference to the drawings. Explanation similar to the explanation of the fourth exemplary embodiment concerning FIGS. 42 through 57 is not repeated herein.

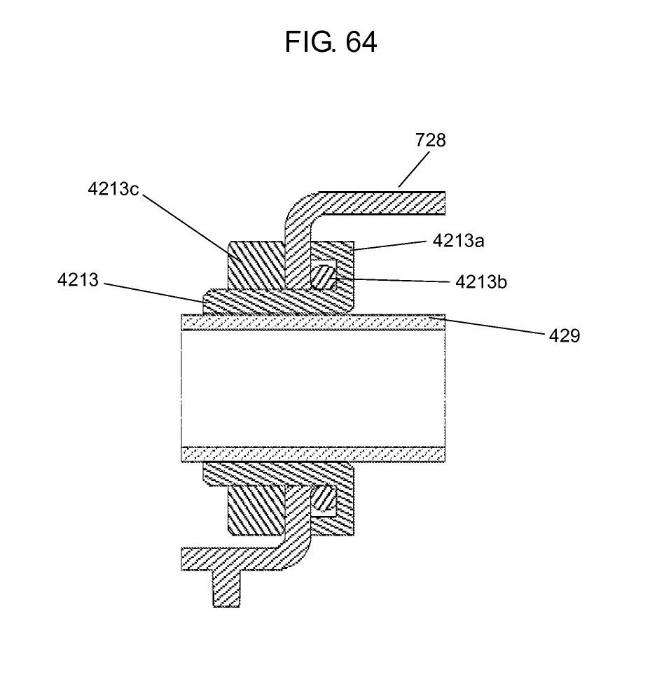

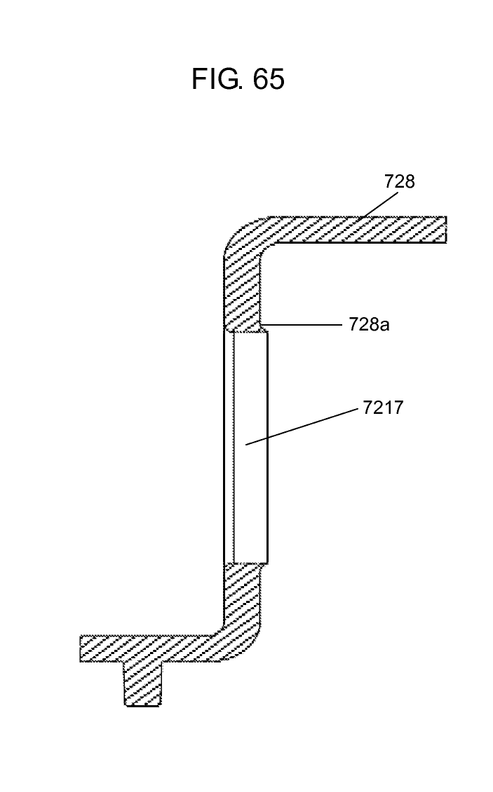

According to the seventh exemplary embodiment, flange 4213a extended in an outer circumferential direction of insertion opening 7212 of cover 728 is provided on a portion of each cylindrical bearing 4213 inside cover 728 as illustrated in FIGS. 53 and 64. Annular packing 4213b is provided between a side surface of flange 4213a on the cover 728 side and an inner surface of cover 728. In this case, even when burr 728a produced on a portion of insertion opening 7212 of cover 728 at the time of formation of insertion opening 7212 generates processing powder during later assembly as illustrated in FIG. 65, for example, this processing powder does not enter cover 728 to cause electric problems. Accordingly, reliability increases.

More specifically, when processing powder of the cover made of carbon fiber reinforced plastics (Carbon Fiber Reinforced Plastics) enters the inside of cover 728, electric problems are caused due to conductivity of the carbon fiber reinforced plastics. According to this exemplary embodiment, however, flange 4213a extended in the outer circumferential direction of insertion opening 7212 of cover 728 is provided on the portion of each cylindrical bearing 4213 inside cover 728. Packing 4213b is provided between the surface of flange 4213a on the cover 728 side and the inner surface of cover 728. Accordingly, the portion of packing 4213b prevents entrance of processing powder into cover 728, thereby avoiding the foregoing electric problems.

For this purpose, it is preferable that packing 4213b is compressed between the surface of flange 4213a on the cover 728 side and the inner surface of cover 728 as illustrated in FIG. 64.

For realizing this compression of packing 4213b between the surface of flange 4213a on the cover 728 side and the inner surface of cover 728, a male screw (not shown) is provided on an outer circumference of a portion of each bearing 4213 outside the cover. Nut 4213c is threadedly connected with and fastened to this male screw portion to compress packing 4213b.

Moreover, for preventing excessive compression of packing 4213b, an outer circumferential end of flange 4213a is bended toward the inside of cover 728 to bring the bended portion into contact with the inside of cover 728 as illustrated in FIG. 64. In this state, further fastening of nut 4213c is avoidable.

According to the seventh embodiment described above, the display device includes a display unit, a cover covering an outer peripheral side or a rear side of the display unit, and cylindrical or bar-shaped attachment shafts that attach the cover to a seat constituent. The cover is made of carbon fiber reinforced plastics (Carbon Fiber Reinforced Plastics). The cover includes insertion holes through each of which a part of the corresponding attachment shaft is inserted into the cover. A cylindrical bearing is attached to each of the insertion holes. One end of the bearing is positioned inside the cover, while another end of the bearing is positioned outside the cover. A part of each attachment shaft is inserted through a through hole of the corresponding bearing into the cover. A flange extended in an outer circumferential direction of each insertion opening of the cover is provided in a portion of each cylindrical bearing inside the cover. Packing is provided between a cover side surface of the flange and an inner surface of the cover. Accordingly, damage to the cover or the attachment shafts is avoidable.

Moreover, according to the seventh exemplary embodiment, a flange is provided on the portion of each cylindrical bearing inside the cover, and extended in the outer circumferential direction of the insertion opening of the cover. The packing is provided between the cover side surface of the flange and the inner surface of the cover. This structure prevents entrance, into the cover, of processing powder generated from the insertion opening portion of the cover during formation of the insertion opening or the like, for example, thereby avoiding electric problems. Accordingly, reliability increases.

### INDUSTRIAL APPLICABILITY

An electronic apparatus according to the present invention is expected to be applicable to an electronic apparatus for home use or for vehicle equipment. A display device according to the present invention is expected to be applicable to a display device equipped on a mobile device such as a vehicle and an airplane.

### REFERENCE MARKS IN THE DRAWINGS

1 Driver's seat
2 Electronic apparatus
3 Body case
4 Body case
5 Opening
6 Display unit
7 Controller
8 Power source unit
9 Memory
10 Audio output unit
11 Reproduction unit
12 Sheet
13 Resin layer
14 Nut
15 Through hole
16 Lower mold
17 Upper mold
18 Electric circuit board
19 Earth pattern
20 Through hole
21 Resist film
22 Bolt
23 Body case fixture
30 Body case
40 Body case
200 Electronic apparatus
400 Body case
421 Front seat
423 Cover member
425 Display device
426 Display unit
427 Cover
428 Cover
429 Attachment shaft
442 Seat constituent
4210 Cover
4211 Protruding portion
4213 Bearing
1815 Projection
1923 Sink
2000 Electronic apparatus
2020 Electric circuit board
2021 Tapping screw
2022 Through hole
2112 Sheet
2113 Resin layer
2114 Through hole
2416 Lower mold
2417 Upper mold
2418 Recess
2419 Pin
300 Body case
3012 Communication unit
3013 Antenna unit
3014 External device
3117 Opening
3320 Electric circuit board
3415 Sheet
3618 Lower mold
3619 Upper mold
3716 Resin layer
4212 Insertion hole
4213a Flange
4213b Packing
4213c Nut
4214 Connecting fitting
4215 Pin
4216 Through hole
4217 Through hole
4219 Attachment screw
4224 Tension member
4225 Attachment portion
4226 Ring
4227 Opening
4228 Rib
424 Head restraint
4419 Attachment screw
4418 Opening
5020 Controller
5021 Memory unit
5022 Power source unit
5023 Audio output unit
5225 Attachment portion
528 Cover
528a Exposure portion
528b Conductive tape
528c Control board
528d Conductor
628 Cover
6225 Attachment portion
628a Exposure portion
628b Control board
628c Conductor
628d Packing
628e Frame
7217 Through hole
728 Cover
728a Burr

1. An electronic apparatus comprising:
a body case; and
an electric circuit board disposed inside the body case,
wherein
the body case includes a carbon fiber sheet, a resin layer covering the sheet, and a conductive nut fixed to the sheet with caulking,
the electric circuit board includes an earth pattern, and a first through hole provided in the earth pattern or in a vicinity of the earth pattern,
a conductive bolt is fastened through the first through hole of the electric circuit board into the nut from a side opposite to the nut, and
the earth pattern of the electric circuit board is electrically connected with the sheet via the nut.

2. The electronic apparatus according to claim 1, wherein one end side of the nut is fixed to the sheet with caulking in a state that the one end side of the nut penetrates a second through hole formed in the sheet.

3. The electronic apparatus according to claim 2, wherein the electric circuit board is in contact with another end side of the nut.

4. The electronic apparatus according to claim 1, wherein a body case fixture is inserted from an outside of the body case into a third through hole formed in the body case to connect the body case fixture with the body case in an electric conductive state.

5. An electronic apparatus comprising:
a body case; and
an electric circuit board or electric circuit part attached to an inner surface side of the body case,
wherein the body case includes a carbon fiber sheet, a resin layer covering each of front and rear surfaces of the sheet, and a projection formed inside the body case by raising a part of the resin layer at a portion of a first through hole formed in the sheet,
the electric circuit board or electric circuit part includes a second through hole, and
a tapping screw is fastened from a side opposite to the projection through the second through hole toward the projection.

6. The electronic apparatus according to claim 5, wherein a thickness of the resin layer is larger in a portion of the projection than in a portion of the sheet.

7. (canceled)

8. (canceled)

9. A motor vehicle that includes the electronic apparatus according to claim 1 inside of the motor vehicle.

10. A display device comprising:
a display unit;
a cover that covers an outer peripheral side or a rear side of the display unit; and
a cylindrical or bar-shaped attachment shaft that attaches the cover to a seat constituent,
wherein the cover is made of carbon fiber reinforced plastics (Carbon Fiber Reinforced Plastics),
the cover includes an insertion hole through which a part of the attachment shaft is inserted into the cover,
a cylindrical bearing is attached to the insertion hole, and
a part of the attachment shaft is inserted through a through hole of the bearing into the cover.

11. The display device according to claim 10, wherein
the attachment shaft is made of metal, and
the attachment shaft and the cover are connected with each other in an electric conductive state.

12. The display device according to claim 10, wherein
the attachment shaft includes first and second attachment shafts,
the insertion hole includes first and second insertion holes,
the bearing includes first and second bearings,
the first and second insertion holes are formed in one and another opposed portions of the cover, respectively,
the first bearing is attached to the first insertion hole,
the second bearing is attached to the second insertion hole,
each of one end sides of the first and second attachment shafts constitutes an attachment portion to be attached to the seat constituent,
another end side of the first attachment shaft is inserted into the cover through a through hole of the first bearing,
another end side of the second attachment shaft is inserted into the cover through a through hole of the second bearing, and
the other end side of the first attachment shaft and the other end side of the second attachment shaft are connected with each other by a connecting fitting inside the cover.

13. The display device according to claim 12, wherein
the first and second attachment shafts and the connecting fitting are made of metal, and
at least one of the first and second attachment shafts and the connecting fitting is connected with the cover in an electric conductive state.

14. The display device according to claim 13, wherein a tension member in contact with an outer circumference of the connecting fitting is attached to the cover.

15. A mobile device comprising a front seat including a metal seat constituent, and a cover member covering the seat constituent,
wherein the attachment shaft of the display device according to claim 10 is inserted into the cover member from an opening formed in the cover member, and
the seat constituent and the attachment shaft are connected with each other inside the cover member.

16. (canceled)

17. (canceled)

18. (canceled)

19. (canceled)

20. (canceled)

21. (canceled)

22. (canceled)

23. (canceled)

24. (canceled)

25. (canceled)

26. (canceled)

27. (canceled)

28. (canceled)

29. (canceled)

30. (canceled)

31. (canceled)

32. (canceled)

33. (canceled)

34. (canceled)

35. (canceled)

36. (canceled)

37. (canceled)

38. (canceled)

39. (canceled)

40. (canceled)

41. (canceled)

42. (canceled)

43. The mobile device according to claim 15, wherein
an opening is formed in an upper part of the front seat, and
a display unit of the display device is attached in such a state as to face a rear side of the front seat.
